(19) United States
(12) Patent Application Publication
(10) Pub. No.: US 2023/0387662 A1
(43) Pub. Date: Nov. 30, 2023

(54) SEMICONDUCTOR LASER ELEMENT

(71) Applicant: Nuvoton Technology Corporation Japan, Kyoto (JP)

(72) Inventors: Yasumitsu KUNOH, Toyama (JP); Atsushi YAMADA, Toyama (JP); Hiroki NAGAI, Toyama (JP); Togo NAKATANI, Toyama (JP); Naoto YANAGITA, Toyama (JP); Masayuki HATA, Osaka (JP)

(21) Appl. No.: 18/358,610

(22) Filed: Jul. 25, 2023

Related U.S. Application Data
(63) Continuation of application No. PCT/JP2021/047705, filed on Dec. 22, 2021.
(60) Provisional application No. 63/143,463, filed on Jan. 29, 2021.

(51) Int. Cl. H01S 5/22; H01S 5/042; H01S 5/30

(52) U.S. Cl. CPC H01S 5/22; H01S 5/0425; H01S 5/305; H01S 5/0421

(57) ABSTRACT

A semiconductor laser element includes a substrate and a semiconductor stack. The semiconductor stack includes an N-side semiconductor layer, an active layer, a P-side semiconductor layer, and a P-type contact layer. The semiconductor stack includes two end faces. Laser light resonates between the two end faces. The semiconductor stack includes: a ridge portion; and a bottom portion surrounding the ridge portion in a top view of the semiconductor stack. The ridge portion protrudes upward from the bottom portion, is spaced apart from the two end faces, and includes at least a portion of the P-type contact layer. A current injection window is provided only on the ridge portion out of a top face of the semiconductor stack, the current injection window being a region into which a current is injected. A distance from a top face of the active layer to the bottom portion is constant.

### CROSS REFERENCE TO RELATED APPLICATIONS

This is a continuation application of PCT International Application No. PCT/JP2021/047705 filed on Dec. 22, 2021, designating the United States of America, which is based on and claims priority of U.S. Provisional Patent Application No. 63/143,463 filed on Jan. 29, 2021. The entire disclosures of the above-identified applications, including the specifications, drawings and claims are incorporated herein by reference in their entirety.

### FIELD

The present disclosure relates to a semiconductor laser element.

BACKGROUND

Conventionally, a semiconductor laser element that generates laser light in a resonator has been known (see, for example, Patent Literature (PTL) 1). The semiconductor laser element disclosed in PTL 1 includes: a semiconductor stack including an N-type cladding layer, an active layer, a P-type cladding layer, and a P-type contact layer; an insulating film disposed on the semiconductor stack and including an opening portion; and a P-side electrode disposed on the insulating film. The opening portion is formed in the insulating film, and a current is supplied from the P-side electrode to the semiconductor stack via the opening portion. The opening portion is not formed in the vicinity of end faces constituting a resonator of the semiconductor laser element. Accordingly, in the semiconductor laser element disclosed in PTL 1, it is intended to reduce catastrophic optical damage (COD) in the vicinity of the end faces by regulating the supply of a current to the vicinity of the end faces.

### CITATION LIST

### Patent Literature

PTL 1: International Publication No. WO 2021/206012

### SUMMARY

### Technical Problem

However, since the P-type contact layer extends from one end face to the other end face in the semiconductor laser element disclosed in PTL 1, a current can be supplied from the P-side electrode disposed in the opening portion of the insulating film to the vicinity of the end faces via the P-type contact layer. For this reason, COD in the vicinity of the end faces can occur in the semiconductor laser element disclosed in PTL 1.

The present disclosure has been conceived to solve such a problem, and has an object to provide a semiconductor laser element capable of reducing COD in the vicinity of end faces.

### Solution to Problem

In order to solve the above-described problem, a semiconductor laser element according to one aspect of the present disclosure is a semiconductor laser element that emits laser light in a multi-transverse mode, the semiconductor laser element including: a substrate; and a semiconductor stack disposed above the substrate, wherein the semiconductor stack includes: an N-side semiconductor layer disposed above the substrate; an active layer disposed above the N-side semiconductor layer; a P-side semiconductor layer disposed above the active layer; and a P-type contact layer disposed above the P-side semiconductor layer, the semiconductor stack includes two end faces that are opposite to each other, the laser light resonates between the two end faces, the semiconductor stack includes a ridge portion and a bottom portion, the ridge portion extending in a resonance direction of the laser light, the bottom portion being a portion of a top face of the semiconductor stack and surrounding the ridge portion in a top view of the semiconductor stack, the ridge portion protrudes upward from the bottom portion, the ridge portion is spaced apart from the two end faces, the ridge portion includes at least a portion of the P-type contact layer, a current injection window is provided only on the ridge portion out of the top face of the semiconductor stack, the current injection window being a region into which a current is injected, and a distance from a top face of the active layer to the bottom portion is constant.

Moreover, in order to solve the above-described problem, a semiconductor laser element according to one aspect of the present disclosure is a semiconductor laser element that emits laser light in a multi-transverse mode, the semiconductor laser element including: a substrate; and a semiconductor stack disposed above the substrate, wherein the semiconductor stack includes: an N-side semiconductor layer disposed above the substrate; an active layer disposed above the N-side semiconductor layer; a P-side semiconductor layer disposed above the active layer; and a P-type contact layer disposed above the P-side semiconductor layer, the semiconductor stack includes two end faces that are opposite to each other, the laser light resonates between the two end faces, the semiconductor stack includes a ridge portion and a bottom portion, the ridge portion extending in a resonance direction of the laser light, the bottom portion being a portion of a top face of the semiconductor stack and surrounding the ridge portion in a top view of the semiconductor stack, the ridge portion protrudes upward from the bottom portion, the ridge portion is spaced apart from the two end faces, the ridge portion includes at least a portion of the P-type contact layer, a current injection window is provided only on the ridge portion out of the top face of the semiconductor stack, the current injection window being a region into which a current is injected, and the P-type contact layer is exposed in the bottom portion.

### Advantageous Effects

The present disclosure provides a semiconductor laser element capable of reducing COD in the vicinity of end faces.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic plan view of an entire configuration of a semiconductor laser element according to an embodiment.

FIG. 2 is a schematic first cross-sectional view of the entire configuration of the semiconductor laser element according to the embodiment.

FIG. 3 is a schematic second cross-sectional view of the entire configuration of the semiconductor laser element according to the embodiment.

FIG. 4 is a schematic third cross-sectional view of the entire configuration of the semiconductor laser element according to the embodiment.

FIG. 5 is a schematic cross-sectional view of a configuration example of an N-side semiconductor layer according to the embodiment.

FIG. 6 is a schematic cross-sectional view of a configuration example of an active layer according to the embodiment.

FIG. 7 is a schematic cross-sectional view of a configuration example of a P-side semiconductor layer according to the embodiment.

FIG. 8 is a cross-sectional view of a model structure used in simulation of the semiconductor laser element according to the embodiment.

FIG. 9 is a graph showing simulation results of current spread in a transverse direction in the semiconductor laser element according to the embodiment.

FIG. 10 is a graph obtained by enlarging part of FIG. 9.

FIG. 11 is a graph showing simulation results of a near-field pattern (NFP) width in the transverse direction in the semiconductor laser element according to the embodiment.

FIG. 12 is a graph showing simulation results of current spread in a resonance direction in the semiconductor laser element according to the embodiment.

FIG. 13 is a graph showing a relationship between an effective refractive index difference and a distance from a top face to a bottom portion of an active layer.

FIG. 14 is a schematic cross-sectional view showing the first step of a semiconductor laser element manufacturing method according to the embodiment.

FIG. 15 is a schematic cross-sectional view showing the second step of the semiconductor laser element manufacturing method according to the embodiment.

FIG. 16 is a schematic first cross-sectional view showing the third step of the semiconductor laser element manufacturing method according to the embodiment.

FIG. 17 is a schematic second cross-sectional view showing the third step of the semiconductor laser element manufacturing method according to the embodiment.

FIG. 18 is a schematic first cross-sectional view showing the fourth step of the semiconductor laser element manufacturing method according to the embodiment.

FIG. 19 is a schematic second cross-sectional view showing the fourth step of the semiconductor laser element manufacturing method according to the embodiment.

FIG. 20 is a schematic first cross-sectional view showing the fifth step of the semiconductor laser element manufacturing method according to the embodiment.

FIG. 21 is a schematic second cross-sectional view showing the fifth step of the semiconductor laser element manufacturing method according to the embodiment.

FIG. 22 is a schematic first cross-sectional view showing the sixth step of the semiconductor laser element manufacturing method according to the embodiment.

FIG. 23 is a schematic second cross-sectional view showing the sixth step of the semiconductor laser element manufacturing method according to the embodiment.

FIG. 24 is a schematic plan view of an entire configuration of a semiconductor laser element according to Variation 4.

FIG. 25 is a schematic plan view of an entire configuration of a semiconductor laser element according to Variation 5.

FIG. 26 is a schematic plan view of an entire configuration of a semiconductor laser element according to Variation 6.

FIG. 27 is a schematic plan view of an entire configuration of a semiconductor laser element according to Variation 7.

FIG. 28 is a schematic plan view of an entire configuration of a semiconductor laser element according to Variation 8.

FIG. 29 is a schematic cross-sectional view of the entire configuration of the semiconductor laser element according to Variation 8.

### DESCRIPTION OF EMBODIMENT

Hereinafter, embodiments of the present disclosure are described with reference to the drawings. It should be noted that each of the subsequently described embodiments shows a general or a specific example of the present disclosure. Accordingly, the numerical values, shapes, materials, constituent elements, the arrangement and connection of the constituent elements, etc. indicated in the following embodiments are mere examples, and thus are not intended to limit the constituent element.

Moreover, the respective figures are schematic diagrams and are not necessarily accurate illustrations. Accordingly, scales etc. in the respective figures are not necessarily uniform. It should be noted that in the figures, elements that are substantially the same are given the same reference signs, and overlapping description is omitted or simplified.

Furthermore, in the Specification, the terms “above” and “below” do not refer to the upward (vertically upward) and downward (vertically downward) in terms of absolute space. Those terms are defined by relative positional relationships based on a stacking order in a stacked configuration. Additionally, the terms “above” and “below” apply not only when two constituent elements are disposed spaced apart and some other constituent element is interposed between the two constituent elements, but also when two constituent elements are disposed in close proximity to each other such that the two constituent elements are in contact with each other.

### Embodiment

A semiconductor laser element according to an embodiment is described below.

### 1. Entire Configuration

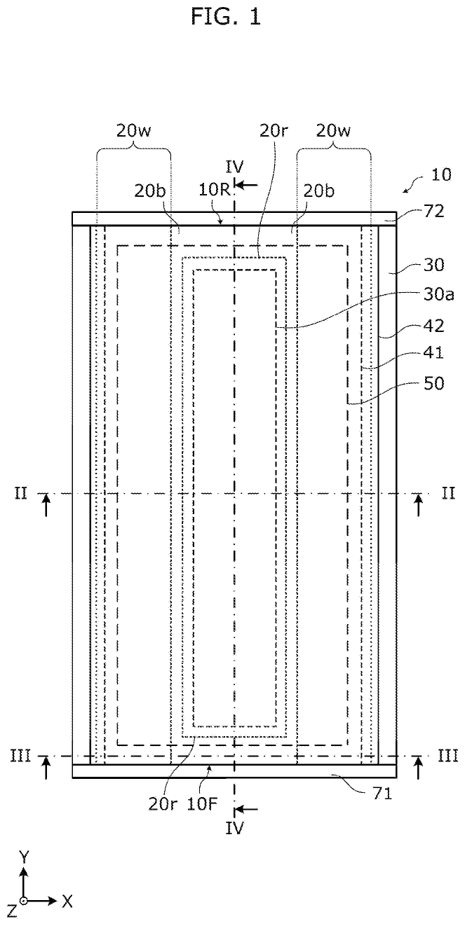

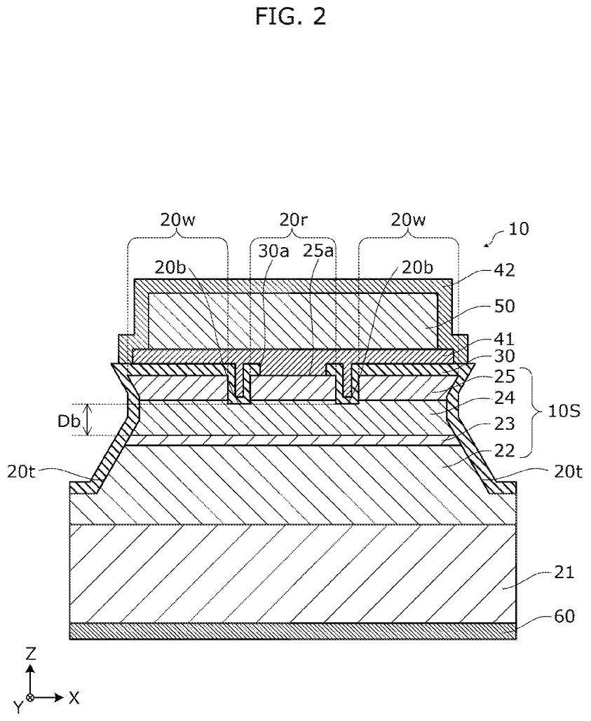

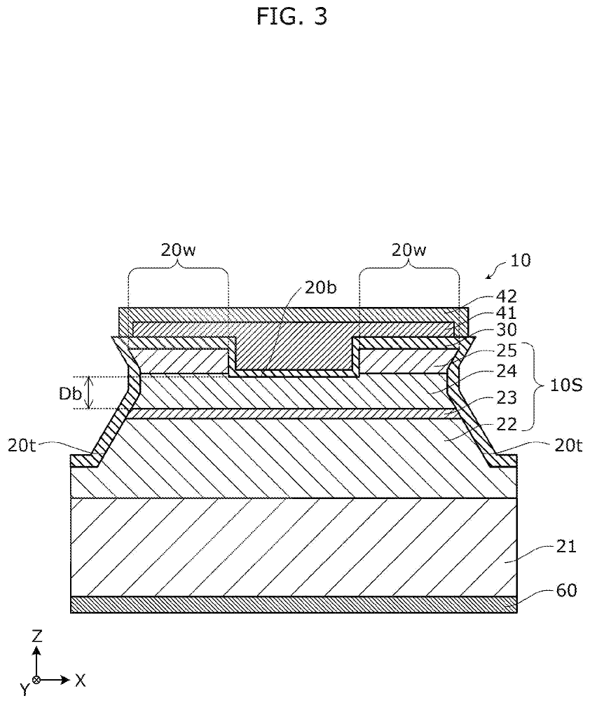

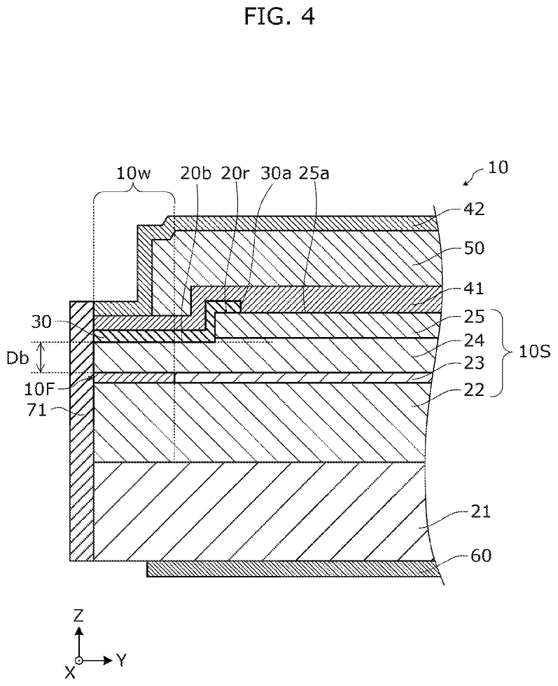

An entire configuration of a semiconductor laser element according to the present embodiment is described with reference to FIG. 1 to FIG. 4. FIG. 1 is a schematic plan view of an entire configuration of semiconductor laser element 10 according to the present embodiment. FIG. 2 to FIG. 4 each are a schematic cross-sectional view of the entire configuration of semiconductor laser element 10 according to the present embodiment. FIG. 2, FIG. 3, and FIG. 4 show respective cross sections taken along line II-II, line III-III, and line IV-IV in FIG. 1. It should be noted that each figure shows an X-axis, a Y-axis, and a Z-axis that are orthogonal to each other. The X-axis, the Y-axis, and the Z-axis constitute a right-handed Cartesian coordinate system. A stacking direction of semiconductor laser element 10 is parallel to the Z-axis direction, and a main emission direction of light (laser light in the present embodiment) is parallel to the Y-axis direction.

Semiconductor laser element 10 is an element that emits laser light in a multi-transverse mode. As shown in FIG. 2, semiconductor laser element 10 includes substrate 21 and semiconductor stack 10S. Semiconductor stack 10S includes two end faces 10F and 10R that are perpendicular to a stacking direction (i.e., the Z-axis direction) and disposed opposite to each other (see FIG. 1). Two end faces 10F and 10R constitute a resonator, and semiconductor stack 10S emits laser light from end face 10F. In the present embodiment, semiconductor stack 10S is located between two end faces 10F and 10R, and includes an optical waveguide that guides laser light. In the present embodiment, semiconductor laser element 10 is of a gain-guiding type. In the present embodiment, semiconductor laser element 10 has a resonator length (i.e., a distance between end face 10F and end face 10R) of at least 2 mm. Semiconductor laser element 10 may have a resonator length of at least 4 mm or less than 2 mm. End face 10F is a front end face through which laser light is emitted, and end face 10R is a rear end face that has a reflectivity higher than a reflectivity of end face 10F.

First end face coating film 71 is disposed on end face 10F, and second end face coating film 72 is disposed on end face 10R. First end face coating film 71 and second end face coating film 72 each are a film for adjusting a laser light reflectivity at a corresponding one of the end faces. In the present embodiment, first end face coating film 71 and second end face coating film 72 each are a multilayer film that includes a dielectric multilayer film. For example, first end face coating film 71 is a multilayer film that includes at least one Al₂O₃ film and at least one Ta₂O₅ film, and second end face coating film 72 is a multilayer film that includes at least one Al₂O₃ film, at least one SiO₂ film, and at least one Ta₂O₅ film. As an example, first end face coating film 71 has a reflectivity of 2%, and second end face coating film 72 has a reflectivity of 95%. It should be noted that each of two end faces of substrate 21 in a resonance direction is on the same plane as a corresponding one of end faces 10F and 10R of semiconductor stack 10S (see FIG. 4). First end face coating film 71 and second end face coating film 72 are disposed on the two end faces of substrate 21 in the resonance direction, respectively. The reflectivities of first end face coating film 71 and second end face coating film 72 are not limited to the above-described reflectivities. For example, when semiconductor laser element 10 is disposed in an external resonator, first end face coating film 71 may have a reflectivity of at most 0.2%. This makes it possible to reduce a problem such as the occurrence of a kink resulting from a laser oscillation mode between two end faces of 10F and 10R of semiconductor laser element 10 and a laser oscillation mode of the external resonator competing against each other. Here, a kink refers to a phenomenon in which the power of outputted laser light discontinuously changes in response to a change in a current supplied to semiconductor laser element 10. In other words, a kink refers to a phenomenon in which points that discontinuously change appear in a graph showing a relationship between a current supplied to semiconductor laser element 10 and the power of outputted laser light.

Semiconductor laser element 10 according to the present embodiment emits laser light having a wavelength of at least 900 nm and at most 980 nm. Semiconductor stack 10S of semiconductor laser element 10 includes, for example, a group III-V compound semiconductor comprising an AlGaInAs-based material. Semiconductor laser element 10 emits, for example, laser light in a wavelength range including 976 nm. Moreover, although the details are described later, semiconductor laser element 10 has a window mirror structure. To put it differently, as shown in FIG. 4, semiconductor stack 10S of semiconductor laser element 10 includes window region 10w adjacent to, out of the two end faces, end face 10F (i.e., the front end face) through which laser light is emitted. In the present embodiment, window region 10w is in contact with end face 10F. It should be noted that semiconductor stack 10S may further include window region 10w adjacent to end face 10R. In the present embodiment, semiconductor stack 10S includes window region 10w adjacent to end face 10R.

As shown in FIG. 2, semiconductor laser element 10 includes substrate 21, semiconductor stack 10S, insulating film 30, first P-side electrode 41, pad electrode 50, second P-side electrode 42, and N-side electrode 60.

Substrate 21 is a plate-shaped component that is a base of semiconductor laser element 10. Substrate 21 is a flat plate-shaped component including a principal surface that is uniformly flat. Substrate 21 is a semiconductor substrate such as a GaAs substrate or an insulating substrate such as a sapphire substrate. In the present embodiment, substrate 21 is an N-type GaAs substrate.

Semiconductor stack 10S is a stack disposed above substrate 21. Semiconductor stack 10S includes a plurality of semiconductor layers stacked in the stacking direction (i.e., the Z-axis direction in each figure). In the present embodiment, semiconductor stack 10S includes N-side semiconductor layer 22, active layer 23, P-side semiconductor layer 24, and P-type contact layer 25. As shown in FIG. 1, semiconductor stack 10S includes: ridge portion 20r that extends in a resonance direction of laser light; and bottom portion that surrounds ridge portion 20r in a top view of semiconductor stack 10S. Here, bottom portion 20b is a portion of the top face of semiconductor stack 10S. As shown in FIG. 2, ridge portion 20r protrudes upward from bottom portion 20b and includes at least a portion of P-type contact layer 25. Moreover, as shown in FIG. 1 and FIG. 4, ridge portion 20r is spaced apart from two end faces 10F and Ridge portion 20r of semiconductor stack 10S serves as an optical waveguide of semiconductor laser element 10. In the present embodiment, ridge portion 20r has a width (i.e., a size in the X-axis direction) of 230 μm.

As shown in FIG. 2 to FIG. 4, distance Db from the top face of active layer 23 to bottom portion 20b in the stacking direction is constant in the present embodiment. In other words, bottom portion is located on a flat surface perpendicular to the stacking direction. Accordingly, it is possible to form entire bottom portion 20b simultaneously by, for example, etching. It should be noted that the configuration in which distance Db is constant includes not only a configuration in which distance Db is the same at any position of bottom portion 20b but also a configuration in which distance Db is substantially the same. For example, the configuration in which distance Db is constant includes a configuration in which distance Db has a margin of error of at most 5%. In the present embodiment, as shown in FIG. 2 to FIG. 4, P-side semiconductor layer 24 is exposed in bottom portion 20b. To put it differently, distance Db is less than or equal to the thickness of P-side semiconductor layer 24. It should be noted that the configuration of bottom portion 20b according to the present embodiment is not limited to this example. In other words, distance Db from the top face of active layer 23 to bottom portion 20b in the stacking direction need not be constant in the present embodiment. For example, bottom portion 20b may include a region inclined relative to an XY plane, or include a step portion.

As shown in FIG. 1, FIG. 2, and FIG. 4, current injection window 25a is provided only on ridge portion 20r out of the top face of semiconductor stack 10S. Current injection window 25a is a region in which P-type contact layer 25 included in semiconductor stack 10S is in contact with first P-side electrode 41.

Moreover, as shown in FIG. 1, semiconductor stack 10S includes two wing portions 20w each of which includes a portion of P-type contact layer 25 and extends in the resonance direction. At least a portion of ridge portion 20r is disposed between two wing portions in the top view of semiconductor stack 10S. Each of two wing portions 20w is adjacent to ridge portion 20r with bottom portion 20b being interposed therebetween. As shown in FIG. 2 and FIG. 3, two wing portions 20w protrude upward from bottom portion 20b. The height of two wing portions 20w from bottom portion 20b is equal to the height of ridge portion 20r from bottom portion 20b. Accordingly, for example, since stress applied to semiconductor laser element 10 is dispersed to wing portions 20w when semiconductor laser element is mounted, it is possible to prevent the stress from being concentrated only on ridge portion 20r. For this reason, it is possible to prevent ridge portion 20r from being damaged.

It should be noted that the configuration in which the height of two wing portions 20w from bottom portion 20b is equal to the height of ridge portion 20r from bottom portion 20b includes not only a configuration in which the heights are completely equal but also a configuration in which the heights are substantially equal. For example, a configuration in which the heights have a margin of error of at most 5% is also included in the configuration in which the heights are equal.

Each of two wing portions 20w extends to two end faces 10F and 10R. In the present embodiment, each of two wing portions 20w extends from end face 10F to end face 10R. Accordingly, it is possible to reduce stress applied to ridge portion 20r in the vicinity of end faces 10F and 10R on which stress is readily concentrated when semiconductor laser element 10 is mounted. For this reason, it is possible to prevent ridge portion 20r from being damaged.

The width of bottom portion 20b between ridge portion 20r and wing portion 20w (i.e., a size in the X-axis direction) may be set to at least 5 μm and at most 30 μm. This makes it possible to reduce shear stress outside ridge portion 20r. Since increasing the width of bottom portion 20b excessively causes weight at the time of mounting to be concentrated on ridge portion 20r that becomes a current injection region, the width of bottom portion 20b between ridge portion 20r and wing portion 20w may be set to at least 10 μm and at most 20 μm. Accordingly, it is possible to effectively prevent the rotation of a polarization plane due to the shear stress, and reduce the impact of the shear stress on laser light propagating through an optical waveguide.

Moreover, separation trenches 20t are provided in the both end portions of semiconductor stack 10S in the X-axis direction. Separation trench 20t is a trench used when semiconductor stack 10S is diced.

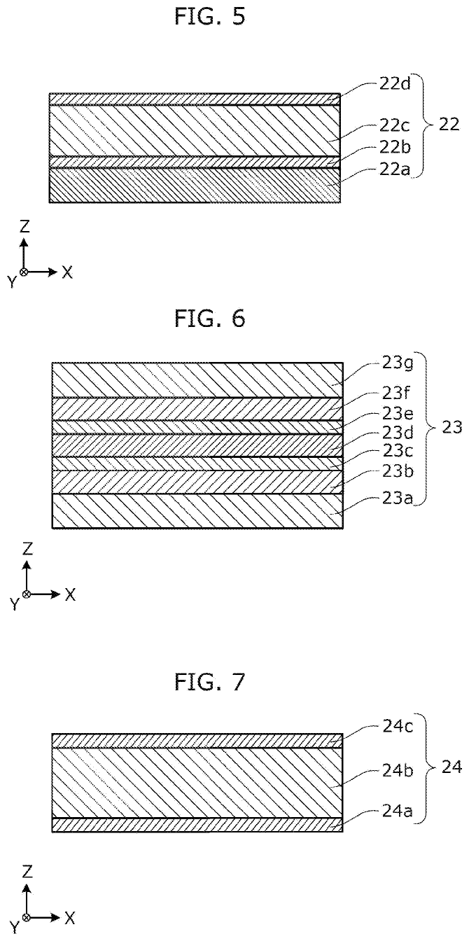

N-side semiconductor layer 22 is an example of a first semiconductor layer of a first conductivity type disposed above substrate 21 and below active layer 23. Hereinafter, a configuration example of N-side semiconductor layer 22 according to the present embodiment is described with reference to FIG. 5. FIG. 5 is a schematic cross-sectional view of a configuration example of N-side semiconductor layer 22 according to the present embodiment. As shown in FIG. 5, in the present embodiment, N-side semiconductor layer 22 includes N-type buffer layer 22a, first N-type composition gradient layer 22b, N-type cladding layer 22c, and second N-type composition gradient layer 22d. N-type buffer layer 22a, first N-type composition gradient layer 22b, N-type cladding layer 22c, and second N-type composition gradient layer 22d each are an N-type semiconductor layer in which impurities are intentionally doped, for example, an N-type GaAs layer or an N-type AlGaAs layer. Examples of impurities with which each layer of N-side semiconductor layer 22 is doped include silicon (Si).

N-type buffer layer 22a is, for example, an N-type semiconductor layer having a thickness of at most 1.0 μm. By causing the thickness to be small as above, it is possible to prevent an energy shift amount in window region 10w from decreasing due to the impact of the impurities contained in N-type buffer layer 22a when window region 10w is formed by thermal diffusion. In order to increase the energy shift amount in window region 10w, N-type buffer layer 22a may have a thickness of at most 0.5 μm. In the present embodiment, N-type buffer layer 22a is an N-type GaAs layer having a thickness of 0.50 μm.

N-type cladding layer 22c is an N-type semiconductor layer that is disposed above first N-type composition gradient layer 22b and has a refractive index lower than a refractive index of active layer 23. In the present embodiment, N-type cladding layer 22c is an N-type Al_{0.32}Ga_{0.68}As layer having a thickness of 3.00 μm.

First N-type composition gradient layer 22b is a layer that is disposed above N-type buffer layer 22a and whose composition varies in accordance with a position in the stacking direction. Bandgap energy of first N-type composition gradient layer 22b has magnitude between bandgap energy of N-type buffer layer 22a and bandgap energy of N-type cladding layer 22c. The bandgap energy of first N-type composition gradient layer 22b approaches the bandgap energy of N-type cladding layer 22c as the position in the stacking direction approaches N-type cladding layer 22c. The bandgap energy of first N-type composition gradient layer 22b approaches the bandgap energy of N-type buffer layer 22a as the position in the stacking direction approaches N-type buffer layer 22a. Since N-side semiconductor layer 22 includes first N-type composition gradient layer 22b, a rapid change in bandgap energy between N-type buffer layer 22a and N-type cladding layer 22c is mitigated. Accordingly, it is possible to reduce element resistance of semiconductor laser element 10. In the present embodiment, first N-type composition gradient layer 22b is an N-type Alₓ₁Ga₁₋ₓ₁As layer having a thickness of 0.05 μm. Al composition ratio x1 of first N-type composition gradient layer 22b is 0.15 in the vicinity of an interface with N-type buffer layer 22a, is 0.32 in the vicinity of an interface with N-type cladding layer 22c, and increases as the position in the stacking direction approaches N-type cladding layer 22c.

Second N-type composition gradient layer 22d is a layer that is disposed above N-type cladding layer 22c and whose composition varies in accordance with a position in the stacking direction. Bandgap energy of second N-type composition gradient layer 22d has magnitude between bandgap energy of N-type cladding layer 22c and bandgap energy in an end portion (N-type guide layer 23a) below active layer 23. The bandgap energy of second N-type composition gradient layer 22d approaches the bandgap energy of N-type cladding layer 22c as the position in the stacking direction approaches N-type cladding layer 22c. The bandgap energy of second N-type composition gradient layer 22d approaches the bandgap energy in the end portion below active layer 23 as the position in the stacking direction approaches active layer 23. Since N-side semiconductor layer 22 includes second N-type composition gradient layer 22d, a rapid change in bandgap energy between N-type cladding layer 22c and active layer 23 is mitigated. Accordingly, it is possible to reduce element resistance of semiconductor laser element 10. In the present embodiment, second N-type composition gradient layer 22d is an N-type Alₓ₂Ga₁₋ₓ₂As layer having a thickness of 0.03 μm. Al composition ratio x2 of second N-type composition gradient layer 22d is 0.32 in the vicinity of an interface with N-type cladding layer 22c, is 0.285 in the vicinity of an interface with active layer 23, and decreases as the position in the stacking direction approaches active layer 23.

It should be noted that N-side semiconductor layer 22 need not include N-type buffer layer 22a, first N-type composition gradient layer 22b, and second N-type composition gradient layer 22d. Moreover, N-side semiconductor layer 22 may include another semiconductor layer. For example, N-side semiconductor layer 22 may include an undoped semiconductor layer.

Active layer 23 is a light-emitting layer disposed above N-side semiconductor layer 22. In the present embodiment, active layer 23 in a region other than window region 10w has a quantum well structure. Active layer 23 may include a single quantum well or a plurality of quantum wells. Here, active layer 23 in window region 10w is described. Bandgap energy measured based on photoluminescence of a gain region that is a region of active layer 23 other than window region 10w is denoted by Eg1. Bandgap energy measured based on photoluminescence of a region in which window region 10w is provided in active layer 23 is denoted by Eg2. When a difference between Eg1 and Eg2 is denoted by ΔEg, window region is provided to satisfy ΔEg=Eg2−Eg1=100 meV. In other words, the bandgap energy of active layer 23 in window region 10w is greater than the bandgap energy of active layer 23 in the region other than window region 10w (i.e., in the region having the quantum well structure). Since this makes it possible to prevent active layer 23 from absorbing laser light in the vicinity of end faces 10F and 10R of semiconductor stack 10S, it is possible to reduce the occurrence of COD in the vicinity of end faces 10F and 10R.

Moreover, in the case where window region 10w is provided, when bandgap energy measured based on photoluminescence of a boundary region between the gain region and the region in which window region 10w is provided is denoted by Eg3, Eg2>Eg3>Eg1 may be satisfied. Specifically, bandgap energy of active layer 23 in the vicinity of end face 10F and end face 10R may be greater than the bandgap energy measured based on the photoluminescence of the boundary region between the gain region and the region in which window region 10w is provided, and bandgap energy measured based on photoluminescence of a boundary region between a region in which window region 10w is not provided and the region in which window region 10w is provided may be greater than bandgap energy of active layer 23 in a central portion in the resonance direction.

As shown in FIG. 2 and FIG. 3, a pair of lateral faces (both end faces in the X-axis direction in FIG. 2 and FIG. 3) of active layer 23 are inclined to the stacking direction. This makes it possible to prevent stray light traveling from a region of active layer 23 located below ridge portion 20r to the lateral faces of active layer 23 from returning again to the region located below ridge portion 20r. Accordingly, since it is possible to reduce competition between laser light resonated between end faces 10F and 10R and the stray light, it is possible to stabilize the operation of semiconductor laser element

Hereinafter, a configuration example of active layer 23 according to the present embodiment is described with reference to FIG. 6. FIG. 6 is a schematic cross-sectional view of a configuration example of active layer 23 according to the present embodiment. As shown in FIG. 6, in the present embodiment, active layer 23 includes N-type guide layer 23a, second N-side barrier layer 23b, first N-side barrier layer 23c, well layer 23d, first P-side barrier layer 23e, second P-side barrier layer 23f, and P-type guide layer 23g. As stated above, active layer 23 has a single quantum well structure including a single quantum well.

N-type guide layer 23a is a layer disposed above N-side semiconductor layer 22, and has a refractive index higher than a refractive index of N-side semiconductor layer 22. In the present embodiment, N-type guide layer 23a is an N-type Al_{0.285}Ga_{0.715}As layer having a thickness of 1.05 μm. N-type guide layer 23a is doped with silicon as impurities.

Second N-side barrier layer 23b is a layer that is disposed above N-type guide layer 23a and serves as a barrier to a quantum well. Second N-side barrier layer 23b may include a doped region in which impurities are intentionally doped, and an undoped region in which no impurities are doped. In the present embodiment, second N-side barrier layer 23b includes an N-type layer disposed above N-type guide layer 23a, and an undoped layer disposed above the N-type layer. The N-type layer is an N-type Al_{0.15}Ga_{0.85}As layer having a thickness of 0.0268 μm. The N-type layer is doped with silicon as impurities. The undoped layer is an Al_{0.15}Ga_{0.85}As layer having a thickness of 0.0083 μm.

First N-side barrier layer 23c is a layer that is disposed above second N-side barrier layer 23b and serves as a barrier to a quantum well. First N-side barrier layer 23c may include a doped region in which impurities are intentionally doped, and an undoped region in which no impurities are doped. In this case, the undoped region is disposed in a position closer to well layer 23d than the doped region is. The undoped region of first N-side barrier layer 23c has a thickness of, for example, at least 5 nm. Doping a region of first N-side barrier layer 23c in the vicinity of well layer 23d with impurities causes a reduction in series resistance of semiconductor laser element but waveguide loss increases due to the occurrence of free carrier loss. In contrast, increasing the thickness of the undoped region causes an increase in series resistance of semiconductor laser element 10. In order to reduce the increase in free carrier loss while reducing the increase in series resistance of semiconductor laser element 10, the undoped region may have a thickness of at least 5 nm and at most 40 nm. When a doping concentration of the impurities in N-type guide laser 23a gradually increases with distance from well layer 23d, it is possible to reduce the increase in waveguide loss even when the thickness of the undoped region in first N -side barrier layer 23c is set to at least 20 nm. In the present embodiment, first N-side barrier layer 23c is an undoped Al_{0.50}Ga_{0.32}In_{0.18}As layer having a thickness of 0.0018 μm.

Well layer 23d is a layer that is disposed above first N -side barrier layer 23c and serves as a quantum well. Well layer 23d is disposed between first N-side barrier layer 23c and first P-side barrier layer 23e, and are in contact with each of first N-side barrier layer 23c and first P-side barrier layer 23e. Well layer 23d may have a thickness of at least 0.0060 nm. In the present embodiment, well layer 23d is an undoped In_{0.135}Ga_{0.865}As layer having a thickness of 0.0090 μm.

First P-side barrier layer 23e is a layer that is disposed above well layer 23d and serves as a barrier to a quantum well. First P-side barrier layer 23e may include a doped region in which impurities are intentionally doped, and an undoped region in which no impurities are doped. In this case, the undoped region is disposed in a position closer to well layer 23d than the doped region is. The undoped region of first P-side barrier layer 23e has a thickness of, for example, at least 5 nm. Doping a region of first P-side barrier layer 23e in the vicinity of well layer 23d with impurities causes a reduction in series resistance of semiconductor laser element 10, but waveguide loss increases due to the occurrence of free carrier loss. In contrast, increasing the thickness of the undoped region causes an increase in series resistance of semiconductor laser element 10. In order to reduce the increase in free carrier loss while reducing the increase in series resistance of semiconductor laser element 10, the undoped region may have a thickness of at least 5 nm and at most 40 nm. When a doping concentration of the impurities in P-type guide laser 23g gradually increases with distance from well layer 23d, it is possible to reduce the increase in waveguide loss even when the thickness of the undoped region in first P-side barrier layer 23e is set to at least 20 nm. In the present embodiment, first P-side barrier layer 23e is an undoped Al_{0.50}Ga_{0.32}In_{0.18}As layer having a thickness of 0.0018 μm.

Second P-side barrier layer 23f is a layer that is disposed above first P-side barrier layer 23e and serves as a barrier to a quantum well. Second P-side barrier layer 23f may include a doped region in which impurities are intentionally doped, and an undoped region in which no impurities are doped. In the present embodiment, second P-side barrier layer 23f includes an undoped layer disposed above first P-side barrier layer 23e, and a P-type layer disposed above the undoped layer. The undoped layer is an Al_{0.15}Ga_{0.85}As layer having a thickness of 0.0083 μm. The P-type layer is a P-type Al_{0.15}Ga_{0.85}As layer having a thickness of 0.025 μm. The P-type layer is doped with carbon (C) as impurities.

P-type guide layer 23g is a layer disposed above second P-side barrier layer 23f, and has a refractive index higher than a refractive index of P-side semiconductor layer 24. In the present embodiment, P-type guide layer 23g is a P-type Al_{0.28}Ga_{0.72}As layer having a thickness of 0.22 μm. P-type guide layer 23g is doped with carbon as impurities.

P-side semiconductor layer 24 is an example of a second semiconductor layer of a second conductivity type disposed above active layer 23. Hereinafter, a configuration example of P-side semiconductor layer 24 according to the present embodiment is described with reference to FIG. 7. FIG. 7 is a schematic cross-sectional view of a configuration example of P-side semiconductor layer 24 according to the present embodiment. As shown in FIG. 7, in the present embodiment, P-side semiconductor layer 24 includes first P-type composition gradient layer 24a, P-type cladding layer 24b, and second P-type composition gradient layer 24c. First P-type composition gradient layer 24a, P-type cladding layer 24b, and second P-type composition gradient layer 24c each are a P-type semiconductor layer in which impurities are intentionally doped, for example, a P-type AlGaAs layer. Examples of impurities with which each layer of P-side semiconductor layer 24 is doped include carbon. P-side semiconductor layer 24 has an impurity concentration of, for example, less than 1.0×10¹⁹ cm⁻³.

As stated above, P-side semiconductor layer 24 is exposed in bottom portion 20b of semiconductor stack 10S. Second P-type composition gradient layer 24c or P-type cladding layer 24b may be exposed in bottom portion 20b. Bottom portion 20b may be located on the topmost face of second P-type composition gradient layer 24c or may be located between the bottommost and topmost faces of second P-type composition gradient layer 24c. Additionally, bottom portion 20b may be located on the topmost face of P-type cladding layer 24b or may be located between the bottommost and topmost faces of P-type cladding layer 24b.

P-type cladding layer 24b is a P-type semiconductor layer that is disposed above first P-type composition gradient layer 24a and has a refractive index lower than a refractive index of active layer 23. In the present embodiment, P-type cladding layer 24b is a P-type Al_{0.70}Ga_{0.30}As layer having a thickness of 0.75 μm.

First P-type composition gradient layer 24a is a layer that is disposed above active layer 23 and whose composition varies in accordance with a position in the stacking direction. Bandgap energy of first P-type composition gradient layer 24a has magnitude between bandgap energy in an upper end portion (P-type guide layer 23g) of active layer 23 and bandgap energy of P-type cladding layer 24b. The bandgap energy of first P-type composition gradient layer 24a approaches the bandgap energy of P-type cladding layer 24b as the position in the stacking direction approaches P-type cladding layer 24b. The bandgap energy of first P-type composition gradient layer 24a approaches the bandgap energy of the upper end portion of active layer 23 as the position in the stacking direction approaches active layer 23. Since P-side semiconductor layer 24 includes first P-type composition gradient layer 24a, a rapid change in bandgap energy between active layer 23 and P-type cladding layer 24b is mitigated. Accordingly, it is possible to reduce element resistance of semiconductor laser element 10. In the present embodiment, first P-type composition gradient layer 24a is a P-type Al_{y1}Ga_{1-y1}As layer having a thickness of 0.05 μm. Al composition ratio y1 of first P-type composition gradient layer 24a is 0.28 in the vicinity of an interface with active layer 23, is 0.70 in the vicinity of an interface with P-type cladding layer 24b, and increases as the position in the stacking direction approaches P-type cladding layer 24b.

Second P-type composition gradient layer 24c is a layer that is disposed above P-type cladding layer 24b and whose composition varies in accordance with a position in the stacking direction. Bandgap energy of second P-type composition gradient layer 24c has magnitude between bandgap energy of P-type cladding layer 24b and bandgap energy of P-type contact layer 25. The bandgap energy of second P-type composition gradient layer 24c approaches the bandgap energy of P-type cladding layer 24b as the position in the stacking direction approaches P-type cladding layer 24b. The bandgap energy of second P-type composition gradient layer 24c approaches the bandgap energy of P-type contact layer 25 as the position in the stacking direction approaches P-type contact layer 25. Since P-side semiconductor layer 24 includes second P-type composition gradient layer 24c, a rapid change in bandgap energy between P-type cladding layer 24b and P-type contact layer 25 is mitigated. Accordingly, it is possible to reduce element resistance of semiconductor laser element 10. In the present embodiment, second P-type composition gradient layer 24c is a P-type Al_{y2}Ga_{1-y2}As layer having a thickness of 0.05 μm. Al composition ratio y2 of second P-type composition gradient layer 24c is 0.70 in the vicinity of an interface with P-type cladding layer 24b, is 0.15 in the vicinity of an interface with P-type contact layer 25, and decreases as the position in the stacking direction approaches P-type contact layer 25.

P-type contact layer 25 is a layer disposed above P-side semiconductor layer 24. P-type contact layer 25 is disposed below first P-side electrode 41 and is in contact with first P-side electrode 41. P-type contact layer 25 is a P-type semiconductor layer in which impurities are intentionally doped, for example, a P-type GaAs layer. Examples of impurities with which P-type contact layer 25 is doped include carbon. P-type contact layer 25 has a doping concentration of, for example, at least 1.0×10¹⁹ cm⁻³. In the present embodiment, P-type contact layer 25 is a P-type GaAs layer having a thickness of 0.25 μm.

Insulating film 30 is a film having an electrical insulating property disposed above semiconductor stack 10S, and serves as a current blocking film. As shown in FIG. 1, FIG. 2, and FIG. 4, insulating film 30 covers the pair of lateral faces of active layer 23 (i.e., the both end faces of active layer 23 in the X-axis direction shown in FIG. 2 and FIG. 3). In the present embodiment, insulating film 30 covers the lateral faces of N-side semiconductor layer 22, active layer 23, P-side semiconductor layer 24, and P-type contact layer 25. Moreover, insulating film 30 covers the entirety of the top face of semiconductor stack 10S other than current injection window 25a. Furthermore, as shown in FIG. 1, FIG. 2, and FIG. 4, insulating film 30 covers an outer edge portion of current injection window 25a on the top face of ridge portion 20r. Insulating film 30 includes opening portion 30a in a region corresponding to current injection window 25a. Opening portion 30a is an opening formed in a portion of insulating film 30 disposed above ridge portion 20r. Current injection window 25a is provided on the top face of ridge portion 20r by disposing first P-side electrode 41 in opening portion 30a of insulating film 30. Insulating film 30 includes an insulating material such as SiN and SiO₂.

As shown in FIG. 2 to FIG. 4, insulating film 30 is disposed on bottom portion 20b of semiconductor stack 10S. A region of bottom portion 20b in which insulating film 30 is disposed (i.e., a face that is a portion of bottom portion 20b and an interface with insulating film may be oxidized. In other words, an oxygen concentration in bottom portion 20b may be higher than an oxygen concentration inside semiconductor stack 10S. The inside of semiconductor stack 10S means, for example, a region below bottom portion 20b that is a portion of the top face of semiconductor stack 10S. Adhesiveness between insulating film 30 and bottom portion 20b is improved by oxidizing bottom portion 20b. Accordingly, it is possible to prevent semiconductor laser element 10 from being damaged by insulating film 30 coming off.

Examples of a method of promoting oxidization of bottom portion 20b include a method of performing plasma treatment on bottom portion 20b before insulating film 30 is provided and a method of using chemical solution that promotes oxidization such as compound solution of tartaric acid and hydrogen peroxide solution, in addition to a method of providing, as insulating film 30, a film including oxygen such as SiO₂.

First P-side electrode 41 is a P-side electrode in contact with P-type contact layer 25. First P-side electrode 41 is disposed above ridge portion 20r of semiconductor stack 10S, and is in contact with current injection window 25a of P-type contact layer 25 in opening portion 30a of insulating film 30. In the present embodiment, as shown in FIG. 1 to FIG. 4, first P-side electrode 41 is also disposed above ridge portion 20b of semiconductor stack 10S and wing portions 20w with insulating film 30 being interposed therebetween. First P-side electrode 41 includes, for example, at least one metal from among Pt, Ti, Cr, Ni, Mo, and Au. In the present embodiment, first P-side electrode 41 includes a Ti layer in contact with P-type contact layer 25, a Pt layer stacked on the Ti layer, and an Au layer stacked on the Pt layer.

Pad electrode 50 is an electrode in a pad shape disposed above first P-side electrode 41. In the present embodiment, each of the both ends of pad electrode 50 in the resonance direction is located between a corresponding one of two end faces 10F and 10R and ridge portion 20r. As stated above, pad electrode 50 is not disposed in two end faces 10F and 10R. Pad electrode 50 includes, for example, an Au film.

Second P-side electrode 42 is a P-side electrode disposed above pad electrode 50. In the present embodiment, second P-side electrode 42 covers pad electrode 50. Second P-side electrode 42 includes, for example, at least one metal from among Pt, Ti, Cr, Ni, Mo, and Au. In the present embodiment, second P-side electrode 42 includes a Ti layer, a Pt layer stacked on the Ti layer, and an Au layer stacked on the Pt layer.

N-side electrode 60 is an electrode disposed on a lower principal surface of substrate 21 (i.e., out of two principal surfaces of substrate 21 that are opposite to each other, a principal surface on which semiconductor stack 10S is not disposed). N-side electrode 60 includes, for example, an AuGe film, a Ni film, an Au film, a Ti film, a Pt film, and an Au film that are stacked in stated order from a substrate 21 side.

In semiconductor laser element 10 having the above-described configuration, a peak position of a light intensity distribution in the stacking direction is located in N-side semiconductor layer 22. For this reason, it is possible to minimize free carrier loss and improve the use efficiency of injected carrier to active layer 23. As a result, it is possible to cause semiconductor laser element 10 to operate with low voltage driving, low threshold current, and high slope efficiency, and it is possible to achieve light output of several tens of watts with high efficiency and low current driving.

### 2. Advantageous Effects

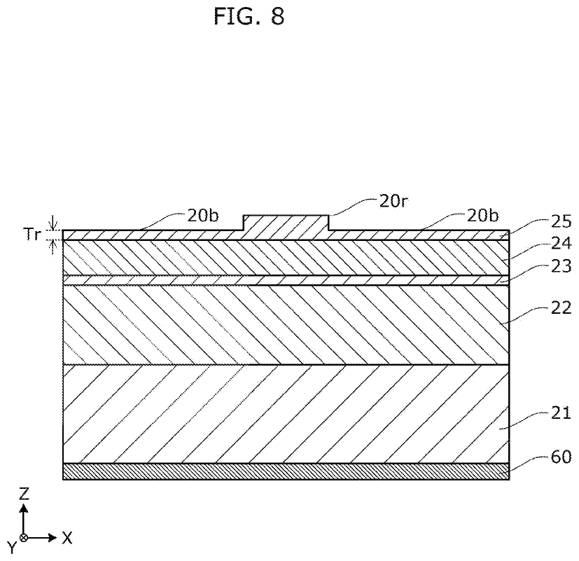

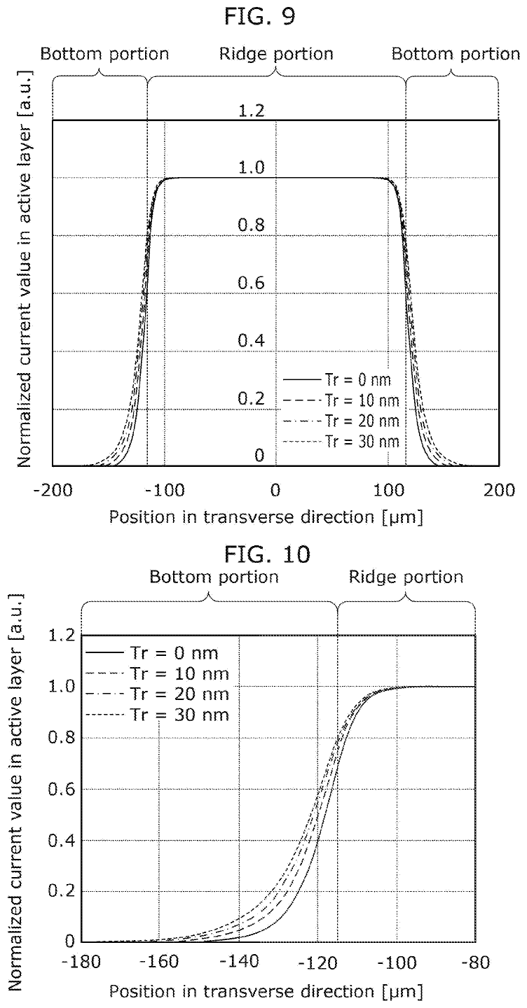

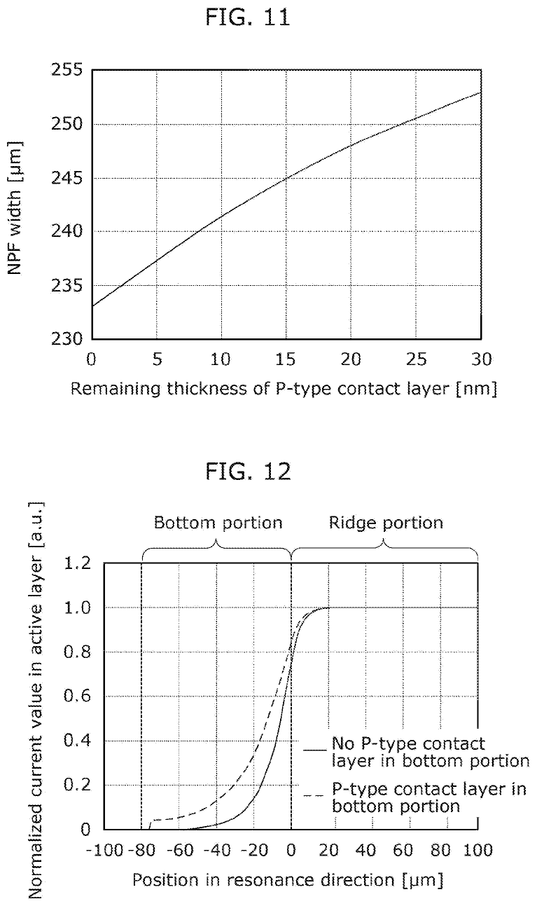

Advantageous effects achieved by semiconductor laser element according to the present embodiment are described below. As stated above, semiconductor laser element 10 according to the present embodiment includes semiconductor stack 10S including ridge portion 20r, and bottom portion 20b surrounds ridge portion 20r as shown in FIG. 1. Moreover, P-side semiconductor layer 24 is exposed in bottom portion 20b. Advantageous effects achieved by these configurations according to the present embodiment are described with reference to FIG. 8 to FIG. 12. FIG. 8 is a cross-sectional view of a model structure used in simulation of semiconductor laser element 10 according to the present embodiment. FIG. 9 is a graph showing simulation results of current spread in a transverse direction (i.e., the X-axis direction) in semiconductor laser element 10 according to the present embodiment. FIG. 10 is a graph obtained by enlarging part of FIG. 9. In FIG. 9 and FIG. 10, the horizontal axis indicates a location in the transverse direction, and the vertical axis indicates a value obtained by normalizing a current value flowing through active layer 23. FIG. 11 is a graph showing simulation results of a near-field pattern (NFP) width in the transverse direction in semiconductor laser element 10 according to the present embodiment. In FIG. 11, the horizontal axis indicates a remaining thickness of P-type contact layer 25 in bottom portion 20b, and the vertical axis indicates an NFP width in the transverse direction. FIG. 12 is a graph showing simulation results of current spread in a resonance direction (i.e., the Y-axis direction) in semiconductor laser element 10 according to the present embodiment.

As shown in FIG. 8, the remaining thickness of P-type contact layer 25 in bottom portion 20b of semiconductor laser element 10 is denoted by Tr. The remaining thickness of P-type contact layer 25 is a distance from a bottom face of P-type contact layer 25 to bottom portion 20b. FIG. 9 and FIG. 10 show simulation results when remaining thickness Tr of P-type contact layer 25 is set to 0 nm, 10 nm, 20 nm, and 30 nm. It should be noted that in the simulation, the width of ridge portion 20r (i.e., a size in the X-axis direction) is set to 230 μm, and the entire top surface of ridge portion 20r is a current injection window region.

By providing bottom portion 20b in a surrounding area of ridge portion 20r in the transverse direction as shown in FIG. 9 and FIG. 10, it is possible to suppress a current leaking from ridge portion 20r in the transverse direction. Moreover, the current leaking from ridge portion 20r in the transverse direction decreases with decrease in the remaining thickness of P-type contact layer 25. In the present embodiment, P-side semiconductor layer 24 is exposed in bottom portion 20b. In other words, since the remaining thickness of P-type contact layer 25 is zero, it is possible to suppress the current leaking from ridge portion 20r in the transverse direction to the minimum. Accordingly, since semiconductor laser element 10 according to the present embodiment is capable of reducing an unavailable current at the time of laser oscillation, semiconductor laser element 10 makes it possible to improve luminous efficiency and prevent laser optical output from decreasing. It should be noted that the configuration of semiconductor laser element 10 according to the present embodiment is not limited to this example. Remaining thickness Tr of P-type contact layer 25 in bottom portion 20b of semiconductor laser element 10 may be greater than zero. To put it differently, P-type contact layer 25 may be exposed in bottom portion 20b. Even in such a configuration, by providing bottom portion 20b in the surrounding area of ridge portion 20r as shown in FIG. 9 and FIG. 10, it is possible to suppress a current leaking from ridge portion 20r to the outside of ridge portion 20r.

As shown in FIG. 11, the NFP width of semiconductor laser element 10 decreases with decrease in the remaining thickness of P-type contact layer 25. In other words, it is possible to decrease the NFP width by providing bottom portion 20b in the surrounding area of ridge portion 20r in the transverse direction and decreasing the remaining thickness of P-type contact layer 25. In the present embodiment, since the remaining thickness of P-type contact layer 25 is zero, it is possible to decease the NFP width to a value close to the width (230 μm) of ridge portion 20r and reduce a divergence angle of laser light.

FIG. 12 shows simulation results in which P-type contact layer is in bottom portion 20b located between ridge portion 20r and end faces 10F and 10R and in which P-type contact layer 25 is not in bottom portion 20b located between ridge portion 20r and end faces 10F and 10R. Remaining thickness Tr of P-type contact layer 25 when P-type contact layer 25 is in bottom portion 20b is 50 nm. Additionally, a distance between ridge portion 20r and end faces 10F and 10R is set to 80 μm, and a length of window region 10w (i.e., a size in the Y-axis direction) is set to 70 μm.

By providing bottom portion 20b between ridge portion 20r and end faces 10F and 10R as shown in FIG. 12, it is possible to suppress a current flowing from ridge portion 20r to the vicinity of end faces 10F and 10R. In addition, by removing P-type contact layer 25 in bottom portion 20b, it is possible to further suppress the current flowing from ridge portion 20r to the vicinity of end faces 10F and 10R. In the present embodiment, P-side semiconductor layer 24 is exposed in bottom portion 20b located between ridge portion 20r and end faces 10F and 10R. To put it differently, since P-type contact layer 25 is not in bottom portion 20b located between ridge portion 20r and end faces 10F and 10R, it is possible to suppress the current flowing from ridge portion 20r to the vicinity of end faces 10F and 10R to the minimum. Accordingly, since semiconductor laser element 10 according to the present embodiment is capable of preventing carrier diffusion into window region 10w provided in the vicinity of end faces 10F and 10R, semiconductor laser element 10 makes it possible to reduce the occurrence of COD. Additionally, in the present embodiment, since it is possible to reduce carrier injection into window region 10w that does not contribute to amplification of laser light, it is possible to improve the luminous efficiency and the laser optical output.

Moreover, as with bottom portion 20b according to the present embodiment, distance Db from the top face of active layer 23 to bottom portion 20b may be less than the thickness of P-side semiconductor layer 24. In other words, a portion of P-side semiconductor layer 24 may be removed in bottom portion 20b. Accordingly, it is possible to further suppress the current flowing from ridge portion 20r to the vicinity of end faces 10F and 10R.

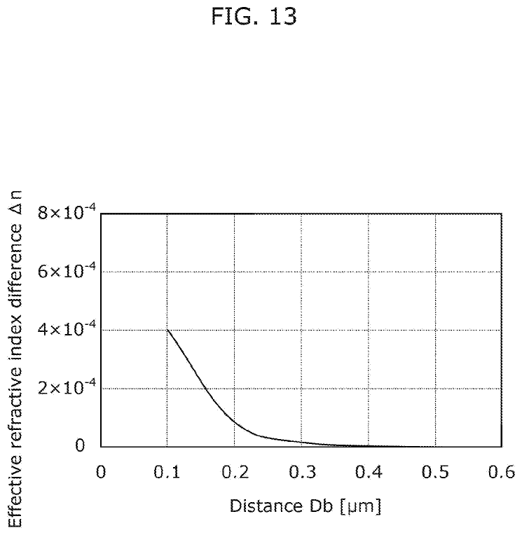

When distance Db decreases, an effective refractive index difference (Δn) between the outside and inside of ridge portion 20r increases as shown in FIG. 13. Since semiconductor laser element oscillates not as a semiconductor laser element of a gain-guiding type but as a semiconductor laser element of a refractive-index-guiding type, a horizontal divergence angle increases. For this reason, when semiconductor laser element 10 is used in a system including optical lenses, a decrease in light reception efficiency is caused. Accordingly, distance Db of bottom portion 20b is set to be in a range that makes it possible to suppress an increase in effective refractive index difference inside the resonator. For example, distance Db may be set to a value in a range (at least 0.4 μm, at most 0.6 μm) in which a change in an effective refractive index difference is small. In addition, distance Db may be set to at least 0.15 μm to cause an effective refractive index difference to be at most 2.0×10⁻⁴. In consequence, it becomes possible to reduce the current spread while suppressing an increase in horizontal divergence angle of laser light.

When a length of window region 10w in the resonance direction is greater than a length of bottom portion 20b located between end face 10F and ridge portion 20r, window region 10w is also provided directly below ridge portion 20r. Since such window region 10w located directly below ridge portion 20r is located relatively far from end faces 10F and 10R, an effect of reducing the occurrence of COD in end faces 10F and 10R is not large. Additionally, since a relatively large current flows through window region 10w located directly below ridge portion 20r, carrier injection into window region 10w that does not contribute to amplification of laser light increases. For this reason, the length of window region 10w in the resonance direction may be less than the length of bottom portion 20b, located between end face 10F and ridge portion 20r, in the resonance direction. Since this makes it possible to reduce the carrier injection into window region 10w, it is possible to improve the luminous efficiency and the laser optical output. The length of bottom portion 20b, located between end face 10F and ridge portion 20r, in the resonance direction may be at least 80 μm.

The length of window region 10w in the resonance direction may be, for example, at least 70 μm. This makes it possible to reduce thermal load generated when window region 10w is provided, it is possible to reduce the degradation of crystallinity in a region of active layer 23 outside window region 10w.

Moreover, in the present embodiment, as shown in FIG. 4, each of the both ends of pad electrode 50 in the resonance direction is located between a corresponding one of two end faces 10F and 10R and ridge portion 20r. In other words, since pad electrode 50 is not disposed at the end faces, when the top face of P-side semiconductor layer 24 is mounted on a mounting base via soldering, it is possible to reduce the mounting stress applied to the vicinity of end faces 10F and 10R. Furthermore, since a portion of pad electrode 50 is located in bottom portion 20b in the vicinity of end faces 10F and 10R, pad electrode 50 is capable of covering the top and lateral faces of ridge portion 20r as well as bottom portion 20b in the vicinity of ridge portion 20r. Accordingly, it is possible to effectively diffuse Joule heat in ridge portion 20r accompanying current injection or heat generated by non-radiation recombination of carriers via pad electrode 50.

In addition, by bringing the ends of pad electrode 50 in the resonance direction close to end faces 10F and 10R, it is possible to improve heat dissipation of end faces 10F and 10R. This makes it possible to reduce deterioration resulting from heat of semiconductor laser element 10. A space between each of the ends of pad electrode 50 in the resonance direction and a corresponding one of end faces 10F and 10R may be at most 15 μm. This makes it possible to further improve the heat dissipation.

### 3. Manufacturing Method

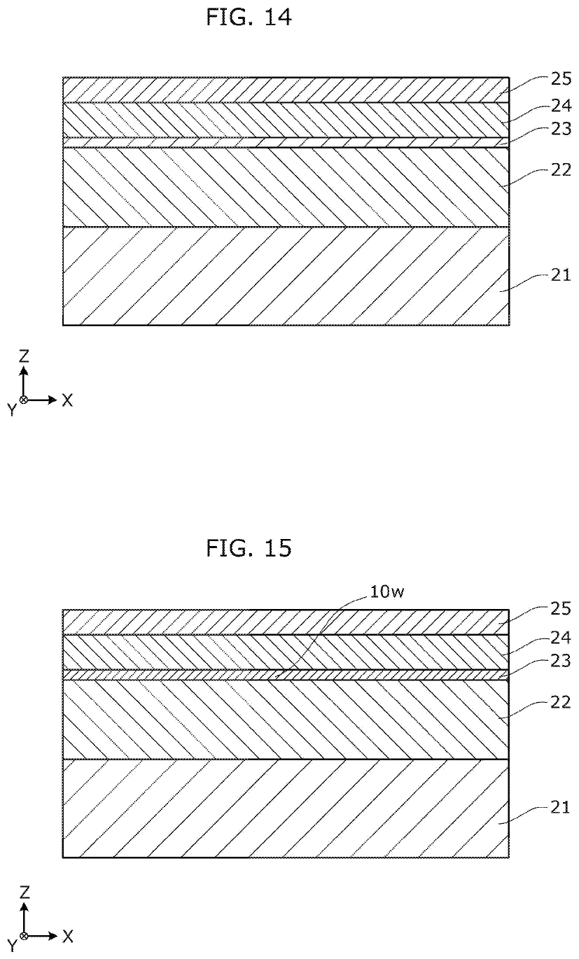

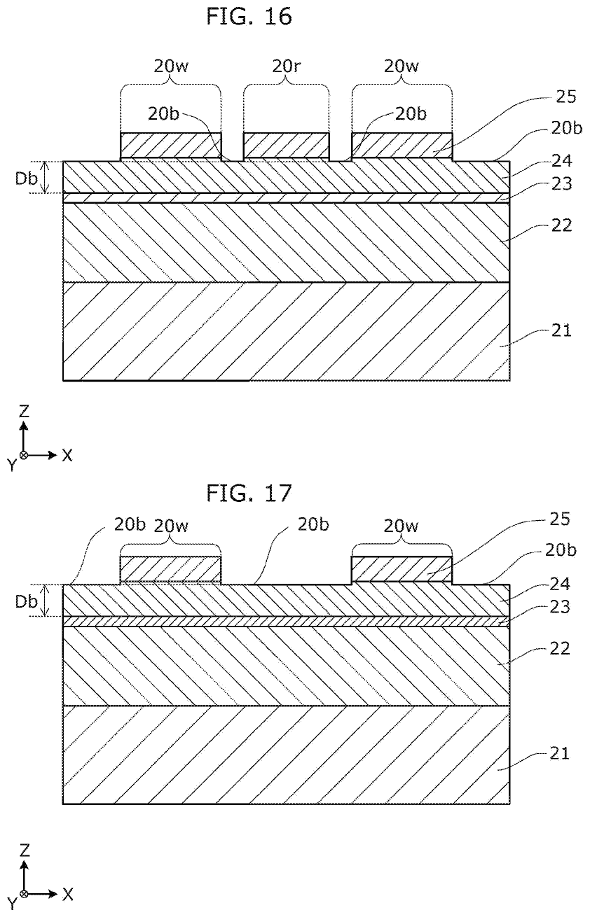

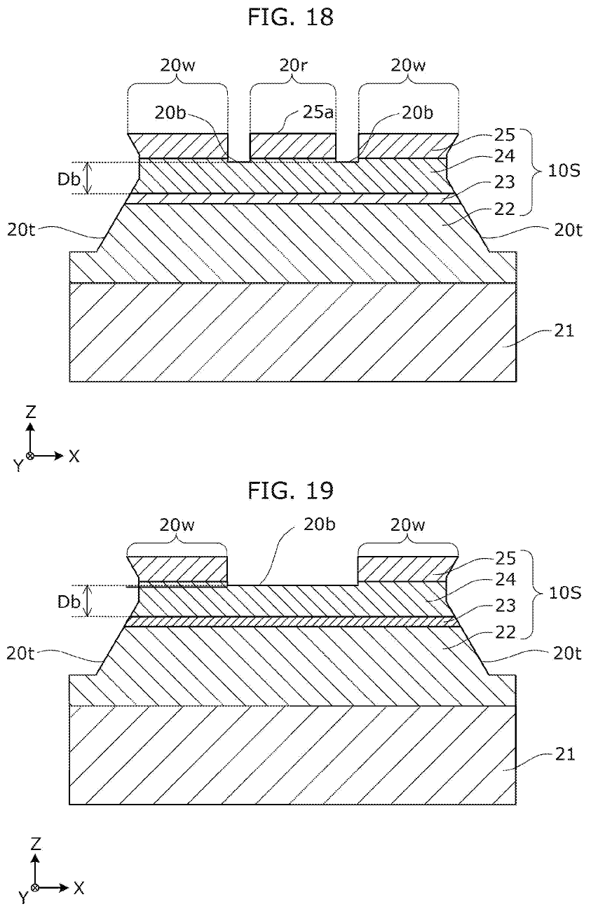

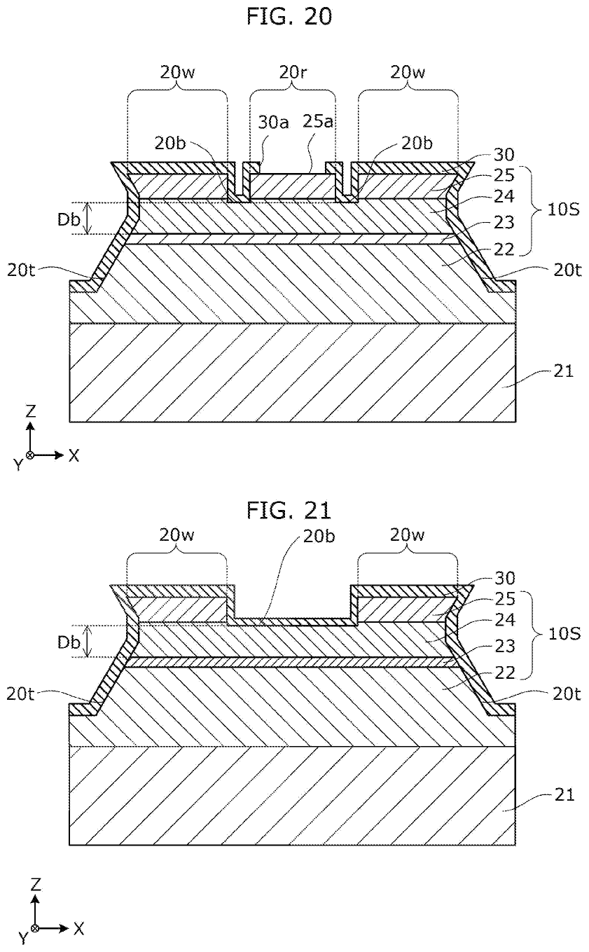

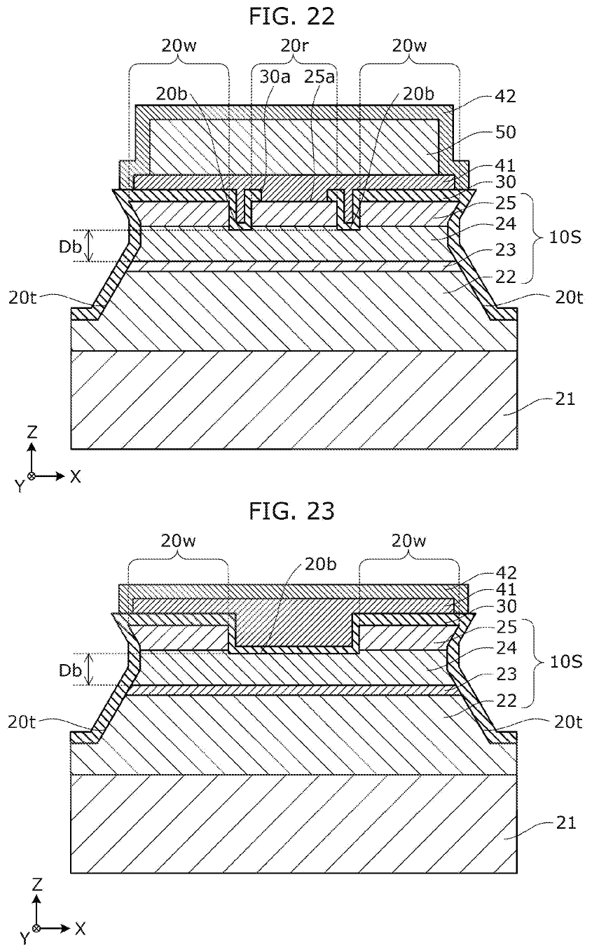

A method of manufacturing semiconductor laser element 10 according to the present embodiment is described with reference to FIG. 2, FIG. 3, and FIG. 14 to FIG. 23. FIG. 14 to FIG. 23 each are a schematic cross-sectional view showing a corresponding one of steps of the method of manufacturing semiconductor laser element according to the present embodiment. FIG. 14, FIG. 16, FIG. 18, FIG. 20, and FIG. 22 each show a cross section of semiconductor laser element 10 in the manufacturing process, taken along line II-II in FIG. 1. FIG. 15, FIG. 17, FIG. 19, FIG. 21, and FIG. 23 each show a cross section of semiconductor laser element 10 in the manufacturing process, taken along line III-III in FIG. 1.

First, as shown in FIG. 14, N-side semiconductor layer 22 is provided on the top face of substrate 21, active layer 23 is provided above N-side semiconductor layer 22, P-side semiconductor layer 24 is provided above active layer 23, and P-type contact layer 25 is provided above P-side semiconductor layer 24.

In the present embodiment, N-side semiconductor layer 22, active layer 23, P-side semiconductor layer 24, and P-type contact layer 25 are stacked on substrate 21 that is an N-type GaAs wafer by growing crystals sequentially using a crystal growth technique based on metalorganic chemical vapor deposition (MOCVD).

N-type buffer layer 22a, first N-type composition gradient layer 22b, N-type cladding layer 22c, and second N-type composition gradient layer 22d are sequentially crystal-grown as N-side semiconductor layer 22 on substrate 21.

N-type guide layer 23a, second N-side barrier layer 23b, first N-side barrier layer 23c, well layer 23d, first P-side barrier layer 23e, second P-side barrier layer 23f, and P-type guide layer 23g are sequentially crystal-grown as active layer 23 on N-side semiconductor layer 22.

First P-type composition gradient layer 24a, P-type cladding layer 24b, and second P-type composition gradient layer 24c are sequentially crystal-grown as P-side semiconductor layer 24 on active layer 23.

Next, as shown in FIG. 15, window region 10w is provided in the vicinity of end faces 10F and 10R. Specifically, window region 10w is provided in end faces 10F and 10R of semiconductor stack 10S. Examples of a method of providing window region 10w generally include an impurity diffusion method and a vacancy diffusion method. In the present embodiment, a window is provided by the vacancy diffusion method. This is because, in super high power semiconductor laser element 10 that outputs more than ten watts per emitter, it is important to reduce the amount of light absorption due to reduction in loss. For example, when window region 10w is provided by the impurity diffusion method, the impurities cause light absorption to increase, and it becomes difficult to reduce light absorption loss. In contrast, since impurities are not used in the vacancy diffusion method, providing window region 10w by the vacancy diffusion method makes it possible to reduce light absorption loss resulting from the impurity introduction.

In the vacancy diffusion method, it is possible to provide window region 10w by performing rapid high-temperature processing on semiconductor stack 10S. For example, by providing a protective film that generates Ga vacancies at the time of high-temperature processing on semiconductor stack 10S in a region in which a window region is provided and then diffusing Ga vacancies by exposing the protective film to extremely high-temperature heat in a range of at least 750° C. and at most 950° C. that is close to a crystal growth temperature, it is possible to disorder the quantum well structure of active layer 23 by interdiffusion of vacancies and group III elements, to achieve a window structure(transparency). As a result, it is possible to increase a band gap of active layer 23 and to cause the region whose quantum well structure is disordered to serve as window region 10w. Additionally, in a region other than window region 10w, it is possible to prevent the quantum well structure from being disordered, by providing a protective film that reduces generation of Ga vacancies at the time of high-temperature processing. It should be noted that although window region 10w is provided by the vacancy diffusion method in the present embodiment, window region 10w may be provided by another method such as the impurity diffusion method.

Then, as shown in FIG. 16, a recessed portion for defining ridge portion 20r and wing portion 20w is provided in P-type contact layer 25. The bottom face of the provided recessed portion is bottom portion 20b. Specifically, a mask including SiO₂ or the like is provided in a predetermined pattern on P-type contact layer 25 by a photolithography technique, and subsequently a recessed portion is provided by a wet etching technique to provide ridge portion 20r and wing portion 20w. On the other hand, as shown in FIG. 17, instead of ridge portion 20r, bottom portion 20b is provided in the vicinity of end face 10F of semiconductor laser element 10. It should be noted that a recessed portion may be provided in a position of each of the both ends of semiconductor laser element 10 in the X-axis direction at which separation trench 20t for dicing is provided. The recessed portion extends in the resonance direction.

Next, as shown in FIG. 18 and FIG. 19, separation trench 20t having an inclined surface is provided at each of the both ends of semiconductor stack 10S in the X-axis direction. Specifically, a mask including SiO₂ or the like is provided in a predetermined pattern on P-side semiconductor layer 24 by the photolithography technique, and subsequently it is possible to provide separation trench 20t inclined at each of the both ends of semiconductor stack 10S in the X-axis direction by etching from P-side semiconductor layer 24 to a portion of N-side semiconductor layer 22 by the wet etching technique. Separation trench 20t is a trench used when semiconductor laser element 10 is diced, and extends in the resonance direction.

It should be noted that it is possible to use, for example, a sulfuric-acid-based etching solution as an etching solution when separation trench 20t is provided. In this case, it is possible to use an etching solution having a ratio of sulfuric acid to hydrogen peroxide solution to water=1:1:10. In addition, an etching solution is not limited to the sulfuric-acid-based etching solution, and may be an organic-acid-based etching solution or an ammonia-based etching solution.

Moreover, separation trench 20t is provided by isotropic wet etching. Accordingly, it is possible to create a constricted structure (i.e., an overhung structure) in a plurality of semiconductor layers by forming an inclined surface on the lateral faces of the plurality of semiconductor layers. An inclination angle of the lateral face of separation trench 20t differs according to an Al composition ratio of an AlGaAs material of each of the plurality of semiconductor layers. It is possible to increase an etching rate by increasing the Al composition ratio of the AlGaAs material. For this reason, in order to form a lateral face having an inclination as shown in FIG. 18 and FIG. 19 in semiconductor stack 10S, it is possible to make an etching rate of P-side semiconductor layer 24 in the transverse direction (the X-axis direction) highest in semiconductor stack 10S by making an Al composition ratio of P-side semiconductor layer 24 highest. This makes it possible to form the narrowest portion (a portion having the smallest width in the horizontal direction) of semiconductor stack 10S in the vicinity of P-side semiconductor layer 24.

Then, after the mask for separation trench 20t is removed by a hydrofluoric-acid-based etching solution, a SiN film is deposited as insulating film 30 on the entire surface above substrate 21 as shown in FIG. 20 and FIG. 21. After that, opening portion 30a is formed by removing a portion of insulating film 30 corresponding to current injection window 25a using the photolithography technique and an etching technique. It should be noted that a portion of insulating film 30 corresponding a current non-injection region is not removed.

It is possible to use, as etching of insulating film 30, wet etching using a hydrofluoric-acid-based etching solution or dry etching such as reactive ion etching (RIE). Moreover, although insulating film 30 is a SiN film, the present embodiment is not limited to this example. Insulating film 30 may be, for example, a SiO₂ film. Here, a technique for providing insulating film 30 that can be employed in the present embodiment may be plasma chemical vapor deposition (hereinafter PCVD). Furthermore, it is possible to use, as source gas for forming insulating film 30, mixed gas of SiH₄, CF₄, NH₃, N₂O, N₂, and the like.

In the present embodiment, a film formation technique is a PCVD method, and mixed gas of SiH₄, NH₃, and N₂ is used as source gas. Although it is possible to set, as film formation conditions, a SiH₄ volume content rate in mixed gas to at least 5% and at most 18%, a temperature of a lower electrode on which a semiconductor substrate is disposed to at least 150° C. and at most 350° C., an intra-chamber pressure to at least 50 Pa and at most 200 Pa, and a RF power to at least 100 W and at most 400 W, the present embodiment is not limited to this example. Film formation conditions may be selected appropriately.

It should be noted that since source gas includes no O₂ when a SiN film is used as insulating film 30, the surface of bottom portion is less easily oxidized. When a SiO₂ film is used as insulating film 30, mixed gas of SiH₄, N₂O, and N₂ is used as source gas.

After that, as shown in FIG. 22 and FIG. 23, a P-side electrode is provided on semiconductor stack 10S. In the present embodiment, first P-side electrode 41, pad electrode 50, and second P-side electrode 42 are provided as the P-side electrode on P-type contact layer 25 in stated order.

Specifically, first P-side electrode 41 including a stacked film of a Ti film, a Pt film, and an Au film is provided as a base electrode by an electron beam evaporation method. Subsequently, pad electrode including an Au plated film is provided by an electrolytic plating method. Afterward, pad electrode 50 in the vicinity of end faces is selectively removed using the photolithography technique or the etching technique and a lift-off technique. It should be noted that it is possible to use an iodine solution as an etching solution for etching pad electrode 50 including the Au plated film. Subsequent to that, second P-side electrode 42 including a stacked film of a Ti film, a Pt film, and an Au film is provided on pad electrode 50 by the electron beam evaporation method. As stated above, although first P-side electrode 41 and second P-side electrode 42 are provided over the almost entire length in the resonance direction, pad electrode 50 is not provided in the vicinity of end faces 10F and 10R.

Next, as shown in FIG. 2 and FIG. 3, N-side electrode 60 is provided on the lower principal surface of substrate 21. Specifically, N-side electrode 60 is provided by forming an AuGe film, a Ni film, an Au film, a Ti film, a Pt film, and an Au film in stated order from the substrate 21 side.

Then, though not shown, substrate 21 on which semiconductor stack 10S is provided is separated into bars by, for example, dicing using a blade or cleaving, and chip separation is subsequently performed by further cutting separation trench 20t as a cutting portion. As a result, it is possible to manufacture diced semiconductor laser element 10.

### 4. Variations

A semiconductor laser element according to each of Variation 1 to Variation 8 is described below. Although a semiconductor laser element according to each of Variation 1 to Variation 3 includes a semiconductor stack similar to semiconductor stack 10S of semiconductor laser element 10 according to the embodiment, the semiconductor laser element differs from semiconductor laser element 10 in part of the layer configuration of semiconductor stack 10S. A semiconductor laser element according to each of Variation 4 to Variation 8 differs from semiconductor laser element 10 according to the embodiment in the configurations of ridge portion 20r, wing portion 20w, and bottom portion 20b of semiconductor stack 10S. Hereinafter, among the configurations of the semiconductor laser elements according to Variation 1 to Variation 8, configurations different from the configuration of semiconductor laser element 10 according to the embodiment are mainly described.

### 4-1. Variation 1

A configuration of a semiconductor laser element according to Variation 1 is described below.

First N-type composition gradient layer 22b of the semiconductor laser element according to Variation 1 is an N-type Alₓ₁Ga₁₋ₓ₁As layer having a thickness of 0.05 μm. Al composition ratio x1 of first N-type composition gradient layer 22b is 0.15 in the vicinity of an interface with N-type buffer layer 22a, is 0.353 in the vicinity of an interface with N-type cladding layer 22c, and increases as the position in the stacking direction approaches N-type cladding layer 22c.

N-type cladding layer 22c of the semiconductor laser element according to Variation 1 is an N-type Al_{0.353}Ga_{0.647}As layer having a thickness of 2.40 μm.

Second N-type composition gradient layer 22d of the semiconductor laser element according to Variation 1 is an N-type Alₓ₂Ga₁₋ₓ₂As layer having a thickness of 0.03 μm. Al composition ratio x2 of second N-type composition gradient layer 22d is 0.353 in the vicinity of an interface with N-type cladding layer 22c, is 0.323 in the vicinity of an interface with active layer 23, and decreases as the position in the stacking direction approaches active layer 23.

N-type guide layer 23a of the semiconductor laser element according to Variation 1 is an N-type Al0.323Ga_{0.677}As layer having a thickness of 0.95 μm.

Second N-side barrier layer 23b of the semiconductor laser element according to Variation 1 includes an N-type layer disposed above N-type guide layer 23a, and an undoped layer disposed above the N-type layer. The N-type layer is an N-type Al_{0.18}Ga_{0.82}As layer having a thickness of 0.0250 μm. The N-type layer is doped with silicon as impurities. The undoped layer is an Al_{0.18}Ga_{0.82}As layer having a thickness of 0.0065 μm.

First N-side barrier layer 23c of the semiconductor laser element according to Variation 1 is an undoped Al_{0.35}Ga_{0.55}In_{0.10}As layer having a thickness of 0.0035 μm.

Well layer 23d of the semiconductor laser element according to Variation 1 is an undoped In_{0.11}Ga_{0.89}As layer having a thickness of 0.0060 μm. First P-side barrier layer 23e of the semiconductor laser element according to Variation 1 is an undoped Al_{0.35}Ga_{0.55}In_{0.10}As layer having a thickness of 0.0035 μm.

Second P-side barrier layer 23f of the semiconductor laser element according to Variation 1 includes an undoped layer disposed above first P-side barrier layer 23e, and a P-type layer disposed above the undoped layer. The undoped layer is an Al_{0.18}Ga_{0.82}As layer having a thickness of 0.0065 μm. The P-type layer is a P-type Al_{0.18}Ga_{0.82}As layer having a thickness of 0.025 μm. The P-type layer is doped with carbon (C) as impurities.

P-type guide layer 23g of the semiconductor laser element according to Variation 1 is a P-type Al_{0.32}Ga_{0.68}As layer having a thickness of 0.1825 μm.

First P-type composition gradient layer 24a of the semiconductor laser element according to Variation 1 is a P-type Al_{y1}Ga_{1-y1}As layer having a thickness of 0.05 μm. Al composition ratio y1 of first P-type composition gradient layer 24a is 0.32 in the vicinity of an interface with active layer 23, is 0.70 in the vicinity of an interface with P-type cladding layer 24b, and increases as the position in the stacking direction approaches P-type cladding layer 24b.

The semiconductor laser element according to Variation 1 having the above configuration achieves the same advantageous effects as semiconductor laser element 10 according to the embodiment. The semiconductor laser element according to Variation 1 is capable of emitting laser light in a wavelength range including 915 nm.

### 4-2. Variation 2

A configuration of a semiconductor laser element according to Variation 2 is described below.

N-type buffer layer 22a of the semiconductor laser element according to Variation 2 is an N-type GaAs layer having a thickness of 0.01 μm.

First N-type composition gradient layer 22b of the semiconductor laser element according to Variation 2 is an N-type Alₓ₁Ga₁₋ₓ₁As layer having a thickness of 0.05 μm. Al composition ratio x1 of first N-type composition gradient layer 22b is 0.15 in the vicinity of an interface with N-type buffer layer 22a, is 0.25 in the vicinity of an interface with N-type cladding layer 22c, and increases as the position in the stacking direction approaches N-type cladding layer 22c.

N-type cladding layer 22c of the semiconductor laser element according to Variation 2 is an N-type Al_{0.25}Ga_{0.75}As layer having a thickness of 1.80 μm.

N-side semiconductor layer 22 of the semiconductor laser element according to Variation 2 does not include second N-type composition gradient layer 22d. In contrast, N-type guide layer 23a in active layer 23 of the semiconductor laser element according to Variation 2 includes: a third N-type guide layer; a second N-type guide layer disposed above the third N-type guide layer; and a first N-type guide layer disposed above the second N-type guide layer. The third N-type guide layer is an N-type Al_{0.25}Ga_{0.75}As layer having a thickness of 0.20 μm. The second N-type guide layer is an N-type Al_{0.23}Ga_{0.77}As layer having a thickness of 0.60 μm. The first N-type guide layer is an N-type Al_{0.21}Ga_{0.79}As layer having a thickness of 0.46 μm.

Second N-side barrier layer 23b of the semiconductor laser element according to Variation 2 includes an N-type layer disposed above N-type guide layer 23a, and an undoped layer disposed above the N-type layer. The N-type layer is an N-type Al_{0.16}Ga_{0.84}As layer having a thickness of 0.0268 μm. The N-type layer is doped with silicon as impurities. The undoped layer is an Al_{0.16}Ga_{0.84}As layer having a thickness of 0.0083 μm.

Second P-side barrier layer 23f of the semiconductor laser element according to Variation 2 is an Al_{0..16}Ga_{0.84}As layer having a thickness of 0.0083 μm.

P-type guide layer 23g of the semiconductor laser element according to Variation 2 is a P-type Al_{z1}Ga_{1-z1}As layer having a thickness of 0.29 μm. Al composition ratio z1 of P-type guide layer 23g is 0.19 in the vicinity of an interface with second P-side barrier layer 23f, is 0.21 in the vicinity of an interface with P-side semiconductor layer 24, and increases as the position in the stacking direction approaches P-side semiconductor layer 24.

First P-type composition gradient layer 24a of the semiconductor laser element according to Variation 2 is a P-type Al_{y1}Ga_{1-y1}As layer having a thickness of 0.05 μm. Al composition ratio y1 of first P-type composition gradient layer 24a is 0.21 in the vicinity of an interface with active layer 23, is 0.70 in the vicinity of an interface with P-type cladding layer 24b, and increases as the position in the stacking direction approaches P-type cladding layer 24b.

P-type cladding layer 24b of the semiconductor laser element according to Variation 2 is a P-type Al_{0.70}Ga_{0.30}As layer having a thickness of 0.70 μm.

The semiconductor laser element according to Variation 2 having the above configuration achieves the same advantageous effects as semiconductor laser element 10 according to the embodiment.

### 4-3. Variation 3

A configuration of a semiconductor laser element according to Variation 3 is described below.

N-type buffer layer 22a of the semiconductor laser element according to Variation 3 is an N-type GaAs layer having a thickness of 0.10 μm.

First N-type composition gradient layer 22b of the semiconductor laser element according to Variation 3 is an N-type Alₓ₁Ga₁₋ₓ₁As layer having a thickness of 0.05 μm. Al composition ratio x1 of first N-type composition gradient layer 22b is 0.15 in the vicinity of an interface with N-type buffer layer 22a, is 0.24 in the vicinity of an interface with N-type cladding layer 22c, and increases as the position in the stacking direction approaches N-type cladding layer 22c.

N-type cladding layer 22c of the semiconductor laser element according to Variation 3 is an N-type Al_{0.24}Ga_{0.76}As layer having a thickness of 1.80 μm.

Second N-type composition gradient layer 22d of the semiconductor laser element according to Variation 3 is an N-type Alₓ₂Ga₁₋ₓ₂As layer having a thickness of 1.00 μm. Al composition ratio x2 of second N-type composition gradient layer 22d is 0.24 in the vicinity of an interface with N-type cladding layer 22c, is 0.22 in the vicinity of an interface with active layer 23, and decreases as the position in the stacking direction approaches active layer 23.

N-type guide layer 23a of the semiconductor laser element according to Variation 3 includes a second N-type guide layer and a first N-type guide layer that is disposed above the second N-type guide layer. The second N-type guide layer is an N-type Al_{z2}Ga_{1-z2}As layer having a thickness of 0.40 μm. Al composition ratio z2 of the second N-type guide layer is 0.22 in the vicinity of an interface with N-side semiconductor layer 22, is 0.19 in the vicinity of an interface with the first N-type guide layer, and decreases as the position in the stacking direction approaches the first N-type guide layer. The first N-type guide layer is an N-type Al_{0.19}Ga_{0.81}As layer having a thickness of 0.09 μm.

Second N-side barrier layer 23b of the semiconductor laser element according to Variation 3 includes an N-type layer disposed above N-type guide layer 23a, and an undoped layer disposed above the N-type layer. The N-type layer is an N-type Al_{0.16}Ga_{0.84}As layer having a thickness of 0.0268 μm. The N-type layer is doped with silicon as impurities. The undoped layer is an Al_{0.16}Ga_{0.84}As layer having a thickness of 0.0083 μm.

Second P-side barrier layer 23f of the semiconductor laser element according to Variation 3 is an Al_{0.16}Ga_{0.84}As layer having a thickness of 0.0083 μm.

P-type guide layer 23g of the semiconductor laser element according to Variation 3 includes a first P-type guide layer and a second P-type guide layer that is disposed above the first P-type guide layer. The first P-type guide layer is a P-type Al_{0.19}Ga_{0.81}As layer having a thickness of 0.01 μm. The second P-type guide layer is a P-type Al_{z1}Ga_{1-z1}As layer having a thickness of 0.28 μm. Al composition ratio z1 of the second P-type guide layer is 0.19 in the vicinity of an interface with the first P-side guide layer, is 0.21 in the vicinity of an interface with P-side semiconductor layer 24, and increases as the position in the stacking direction approaches P-side semiconductor layer 24.

First P-type composition gradient layer 24a of the semiconductor laser element according to Variation 3 is a P-type Al_{y1}Ga_{1-y1}As layer having a thickness of 0.05 μm. Al composition ratio y1 of first P-type composition gradient layer 24a is 0.21 in the vicinity of an interface with active layer 23, is 0.70 in the vicinity of an interface with P-type cladding layer 24b, and increases as the position in the stacking direction approaches P-type cladding layer 24b.

P-type cladding layer 24b of the semiconductor laser element according to Variation 3 is a P-type Al_{0.70}Ga_{0.30}As layer having a thickness of 0.70 μm. The semiconductor laser element according to Variation 3 having the above configuration achieves the same advantageous effects as semiconductor laser element 10 according to the embodiment.

### 4-4. Variation 4

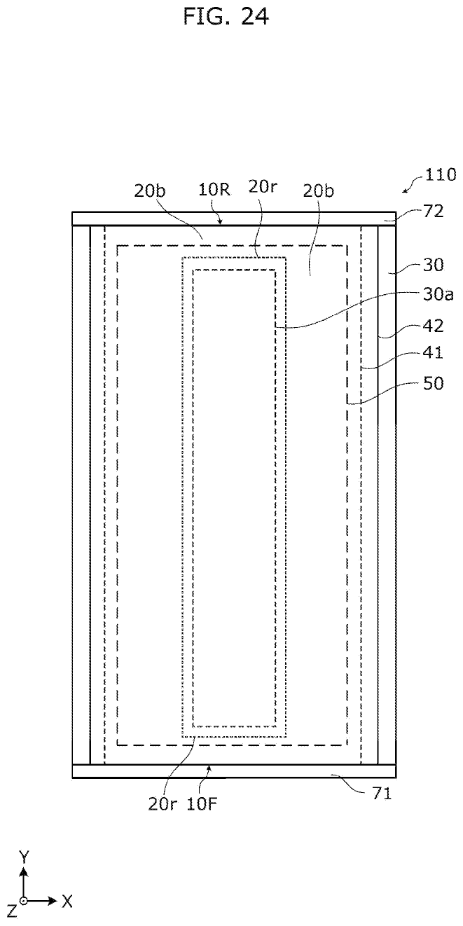

A semiconductor laser element according to Variation 4 is described below with reference to FIG. 24. FIG. 24 is a schematic plan view of an entire configuration of semiconductor laser element 110 according to Variation 4. As shown in FIG. 24, semiconductor laser element 110 according to Variation 4 differs from semiconductor laser element 10 according to the embodiment in not including wing portions 20w. The regions in which wing portions 20w are disposed in semiconductor laser element 10 according to the embodiment are replaced with bottom portions 20b in semiconductor laser element 110 according to Variation 4.

Semiconductor laser element 110 according to Variation 4 having the above configuration achieves the same advantageous effects as semiconductor laser element 10 according to the embodiment, except for the advantageous effect achieved by wing portions 20w.

### 4-5. Variation 5

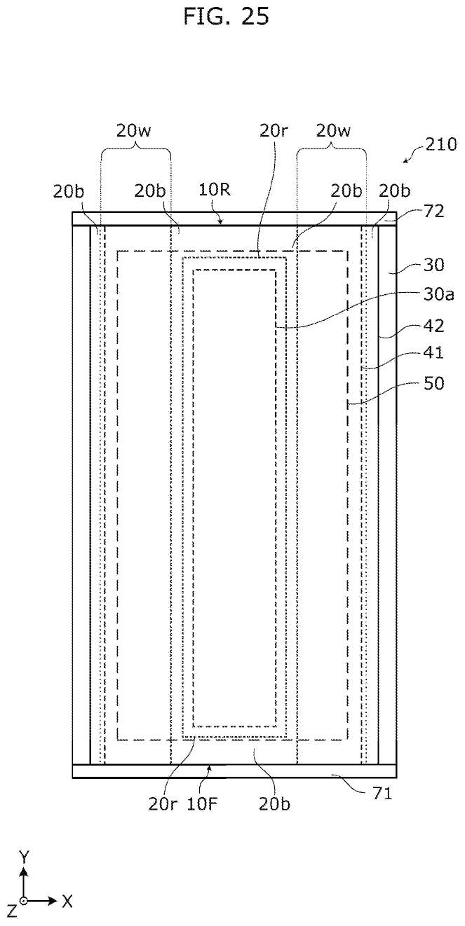

A semiconductor laser element according to Variation 5 is described below with reference to FIG. 25. FIG. 25 is a schematic plan view of an entire configuration of semiconductor laser element 210 according to Variation 5. As shown in FIG. 25, semiconductor laser element 210 according to Variation 5 differs from semiconductor laser element 10 according to the embodiment in including bottom portions 20b outside wing portions 20w in the transverse direction.

Semiconductor laser element 210 according to Variation 5 having the above configuration achieves the same advantageous effects as semiconductor laser element 10 according to the embodiment. In addition, since bottom portions 20b are disposed on both sides of wing portion 20w in the transverse direction, semiconductor laser element 210 according to Variation 5 is capable of improving adhesiveness of insulating film 30 to semiconductor stack 10S.

### 4-6. Variation 6

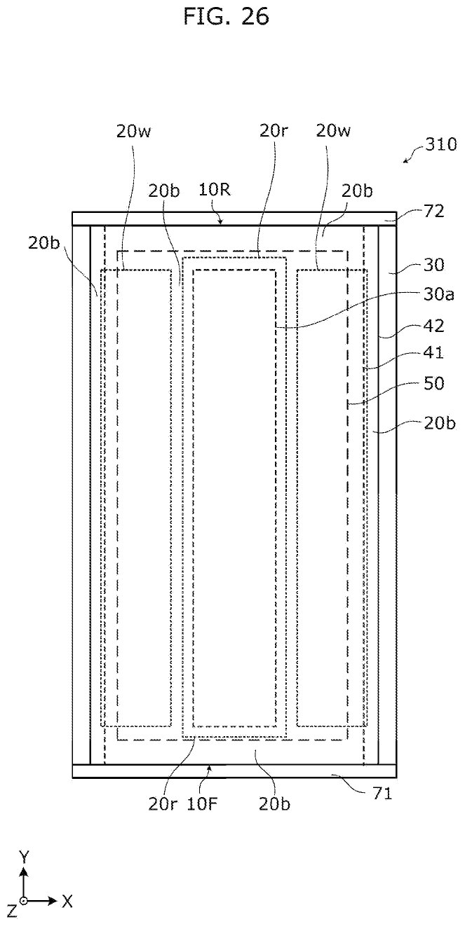

A semiconductor laser element according to Variation 6 is described below with reference to FIG. 26. FIG. 26 is a schematic plan view of an entire configuration of semiconductor laser element 310 according to Variation 6. As shown in FIG. 26, in semiconductor laser element 310 according to Variation 6, bottom portion 20b surrounds wing portion 20w. In other words, bottom portion 20b is disposed outside wing portion 20w in the transverse direction and between wing portion 20w and each of end faces 10F and 10R. In Variation 6, wing portion 20w is spaced apart from end faces 10F and 10R. Additionally, a distance from wing portion 20w to each of end faces 10F and 10R may be greater than a distance from ridge portion to each of end faces 10F and 10R.

Semiconductor laser element 310 according to Variation 6 having the above configuration achieves the same advantageous effects as semiconductor laser element 10 according to the embodiment. In addition, since bottom portion 20b is disposed around wing portion 20w, semiconductor laser element 310 according to Variation 6 is capable of improving adhesiveness of insulating film 30 to semiconductor stack 10S.

### 4-7. Variation 7

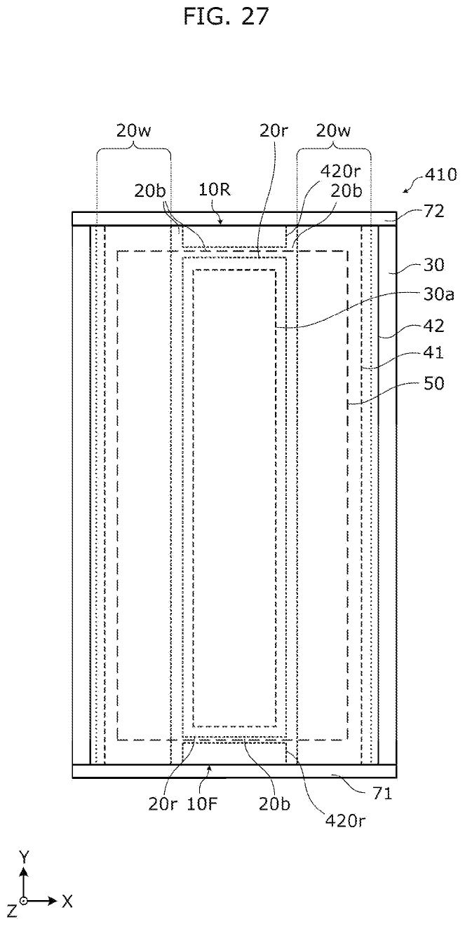

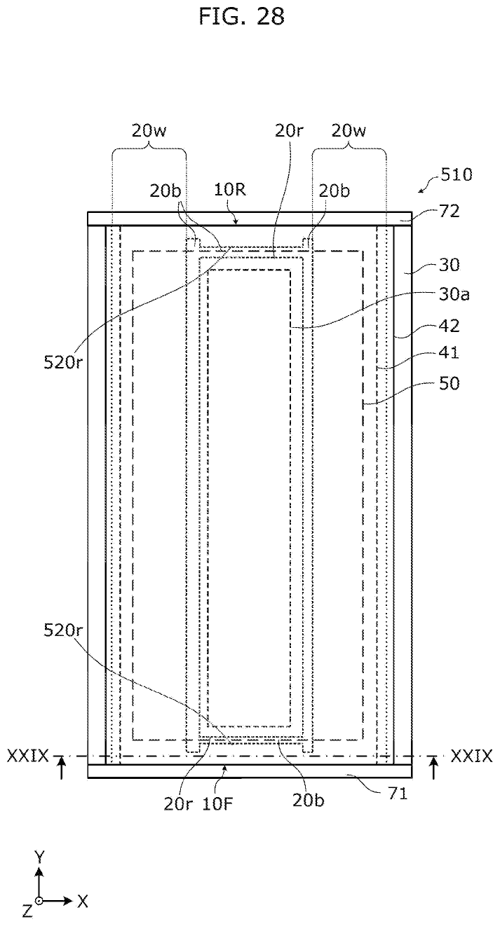

A semiconductor laser element according to Variation 7 is described below with reference to FIG. 27. FIG. 27 is a schematic plan view of an entire configuration of semiconductor laser element 410 according to Variation 7. Semiconductor laser element 410 according to Variation 7 differs from semiconductor laser element 10 according to the embodiment in that dummy ridge portion 420r is disposed between ridge portion 20r and each of end faces 10F and Dummy ridge portion 420r protrudes upward from bottom portion 20b in the same manner as ridge portion 20r. Dummy ridge portion 420r is adjacent to ridge portion 20r with bottom portion 20b being interposed therebetween. In Variation 7, the height of dummy ridge portion 420r from bottom portion 20b is equal to the height of ridge portion 20r from bottom portion 20b. Moreover, the width of dummy ridge portion 420r (i.e., a size in the X-axis direction) is equal to the width of ridge portion 20r and is in a rectangular shape in a top view. Dummy ridge portion 420r is in contact with end face 10F or 10R.

Semiconductor laser element 410 according to Variation 7 having the above configuration achieves the same advantageous effects as semiconductor laser element 10 according to the embodiment. Moreover, since, for example, by semiconductor laser element 410 according to Variation 7 including dummy ridge portion 420r, stress applied to semiconductor laser element 410 is dispersed to dummy ridge portion 420r when semiconductor laser element 410 is mounted, it is possible to prevent the stress from being concentrated only on ridge portion 20r. For this reason, it is possible to prevent ridge portion 20r from being damaged. Furthermore, since adhesiveness between insulating film 30 and bottom portion 20b is poor when an AlGaAs layer is exposed in bottom portion 20b, insulating film 30 is likely to come off easily in a region in which insulating film 30 is in contact with bottom portion 20b. Since semiconductor laser element 410 according to Variation 7 makes it possible to replace a portion of a region that is between end faces 10F and 10R and ridge portion 20r and to which an AlGaAs layer is exposed with dummy ridge portion 420r including GaAs, semiconductor laser element 410 is capable of improving adhesiveness between insulating film 30 and semiconductor stack 10S.

### 4-8. Variation 8

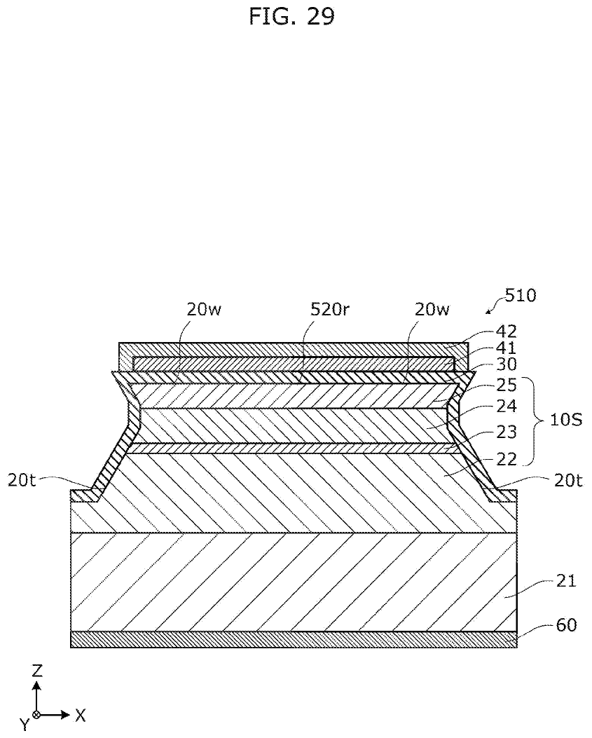

A semiconductor laser element according to Variation 8 is described below with reference to FIG. 28 and FIG. 29. FIG. 28 and FIG. 29 are a schematic plan view and a schematic cross-sectional view of an entire configuration of semiconductor laser element 510 according to Variation 8, respectively. FIG. 29 shows a cross section of the vicinity of end face 10F, taken along line XXIX-XXIX in FIG. 28.

As shown in FIG. 28 and FIG. 29, semiconductor laser element 510 according to Variation 8 differs from semiconductor laser element 10 according to the embodiment in that dummy ridge portion 520r is disposed between ridge portion 20r and each of end faces 10F and 10R in the same manner as in Variation 7. Moreover, dummy ridge portion 520r according to Variation 8 is integrated with wing portion In other words, a region of bottom portion 20b that is between dummy ridge portion 420r according to Variation 7 and wing portion and adjacent to end faces 10F and 10R is replaced with dummy ridge portion 520r. To put it differently, bottom portion 20b is not in contact with end faces 10F and 10R (see FIG. 29).

Semiconductor laser element 510 according to Variation 8 having the above configuration achieves the same advantageous effects as semiconductor laser element 10 according to the embodiment. Moreover, since, for example, by semiconductor laser element 510 according to Variation 8 including dummy ridge portion 520r, stress applied to semiconductor laser element 510 is dispersed to dummy ridge portion 520r when semiconductor laser element 510 is mounted, it is possible to prevent the stress from being concentrated only on ridge portion 20r. For this reason, it is possible to prevent ridge portion 20r from being damaged. Furthermore, since adhesiveness between insulating film 30 and bottom portion 20b is poor when an AlGaAs layer is exposed in bottom portion 20b, insulating film 30 is likely to come off easily in a region in which insulating film 30 is in contact with bottom portion 20b. Since semiconductor laser element 510 according to Variation 8 makes it possible to replace a portion of a region that is between each of end faces 10F and 10R and ridge portion 20r and to which an AlGaAs layer is exposed with dummy ridge portion 520r including GaAs, semiconductor laser element 510 is capable of improving adhesiveness between insulating film 30 and semiconductor stack 10S. Moreover, in semiconductor laser element 510 according to Variation 8, since bottom portion 20b is not in contact with end faces 10F and 10R, an adhesion surface between insulating film 30 and bottom portion 20b having poor adhesiveness is not exposed from each of end faces 10F and 10R. Accordingly, it is possible to further prevent insulating film 30 from coming off.

### Other Variations Etc.

Although the semiconductor laser element according to the present disclosure has been described based on each of the embodiments, the present disclosure is not limited to the embodiment.

For example, in Variation 1 to Variation 8, distance Db of bottom portion 20b from the top face of active layer 23 may be greater than or equal to the thickness of P-side semiconductor layer 24 or may be less than the thickness of P-side semiconductor layer 24. In other words, P-type contact layer 25 may be exposed in bottom portion 20b, and P-side semiconductor layer 24 may be exposed in bottom portion 20b.

Moreover, forms obtained by various modifications to the respective embodiments that can be conceived by a person skilled in the art as well as forms achieved by arbitrarily combining the constituent elements and functions in the respective embodiments are included in the scope of the present disclosure as long as they do not depart from the essence of the present disclosure.

### INDUSTRIAL APPLICABILITY

The semiconductor laser element etc. according to the present disclosure is applicable as a highly efficient light source to, for example, a light source for processing machine.

1. A semiconductor laser element that emits laser light in a multi-transverse mode, the semiconductor laser element comprising:
a substrate; and
a semiconductor stack disposed above the substrate,
wherein the semiconductor stack includes:
an N-side semiconductor layer disposed above the substrate;
an active layer disposed above the N-side semiconductor layer;
a P-side semiconductor layer disposed above the active layer; and
a P-type contact layer disposed above the P-side semiconductor layer,
the semiconductor stack includes two end faces that are opposite to each other,
the laser light resonates between the two end faces,
the semiconductor stack includes a ridge portion and a bottom portion, the ridge portion extending in a resonance direction of the laser light, the bottom portion being a portion of a top face of the semiconductor stack and surrounding the ridge portion in a top view of the semiconductor stack,
the ridge portion protrudes upward from the bottom portion,
the ridge portion is spaced apart from the two end faces,
the ridge portion includes at least a portion of the P-type contact layer,
a current injection window is provided only on the ridge portion out of the top face of the semiconductor stack, the current injection window being a region into which a current is injected, and
a distance from a top face of the active layer to the bottom portion is constant.

2. The semiconductor laser element according to claim 1,
wherein the P-side semiconductor layer is exposed in the bottom portion.

3. A semiconductor laser element that emits laser light in a multi-transverse mode, the semiconductor laser element comprising:
a substrate; and
a semiconductor stack disposed above the substrate,
wherein the semiconductor stack includes:
an N-side semiconductor layer disposed above the substrate;
an active layer disposed above the N-side semiconductor layer;
a P-side semiconductor layer disposed above the active layer; and
a P-type contact layer disposed above the P-side semiconductor layer,
the semiconductor stack includes two end faces that are opposite to each other,
the laser light resonates between the two end faces,
the semiconductor stack includes a ridge portion and a bottom portion, the ridge portion extending in a resonance direction of the laser light, the bottom portion being a portion of a top face of the semiconductor stack and surrounding the ridge portion in a top view of the semiconductor stack,
the ridge portion protrudes upward from the bottom portion,
the ridge portion is spaced apart from the two end faces,
the ridge portion includes at least a portion of the P-type contact layer,
a current injection window is provided only on the ridge portion out of the top face of the semiconductor stack, the current injection window being a region into which a current is injected, and
the P-type contact layer is exposed in the bottom portion.

4. A semiconductor laser element that emits laser light in a multi-transverse mode, the semiconductor laser element comprising:
a substrate; and
a semiconductor stack disposed above the substrate,
wherein the semiconductor stack includes:
an N-side semiconductor layer disposed above the substrate;
an active layer disposed above the N-side semiconductor layer;
a P-side semiconductor layer disposed above the active layer; and
a P-type contact layer disposed above the P-side semiconductor layer,
the semiconductor stack includes two end faces that are opposite to each other,
the laser light resonates between the two end faces,
the semiconductor stack includes a ridge portion and a bottom portion, the ridge portion extending in a resonance direction of the laser light, the bottom portion being a portion of a top face of the semiconductor stack and surrounding the ridge portion in a top view of the semiconductor stack,
the ridge portion protrudes upward from the bottom portion,
the ridge portion is spaced apart from the two end faces,
the ridge portion includes at least a portion of the P-type contact layer,
a current injection window is provided only on the ridge portion out of the top face of the semiconductor stack, the current injection window being a region into which a current is injected,
the semiconductor stack includes a window region adjacent to a front end face through which the laser light is emitted, the front end face being one of the two end faces, and
bandgap energy of the active layer in the window region is greater than bandgap energy of the active layer in a region other than the window region.

5. The semiconductor laser element according to claim 1,
wherein the semiconductor stack includes two wing portions each of which includes a portion of the P-type contact layer and extends in the resonance direction,
at least a portion of the ridge portion is disposed between the two wing portions in the top view of the semiconductor stack,
each of the two wing portions is adjacent to the ridge portion with the bottom portion being interposed therebetween,
the two wing portions protrude upward from the bottom portion,
a height of the two wing portions from the bottom portion is equal to a height of the ridge portion from the bottom portion.

6. The semiconductor laser element according to claim 5,
wherein each of the two wing portions extends to the two end faces.

7. The semiconductor laser element according to claim 1,
wherein the semiconductor stack includes a window region adjacent to a front end face through which the laser light is emitted, the front end face being one of the two end faces, and
bandgap energy of the active layer in the window region is greater than bandgap energy of the active layer in a region other than the window region.

8. The semiconductor laser element according to claim 7,
wherein the active layer in the region other than the window region has a quantum well structure.

9. The semiconductor laser element according to claim 7,
wherein the window region is in contact with the front end face, and
a length of the window region in the resonance direction is less than a length of the bottom portion in the resonance direction, the bottom portion being located between the front end face and the ridge portion.

10. The semiconductor laser element according to claim 1, further comprising:
an insulating film disposed above the semiconductor stack,
wherein the insulating film includes an opening portion in a region corresponding to the current injection window.

11. The semiconductor laser element according to claim 1,
wherein an oxygen concentration in the bottom portion is higher than an oxygen concentration inside the semiconductor stack.

12. The semiconductor laser element according to claim 1, further comprising:
a P-side electrode in contact with the P-type contact layer; and a pad electrode disposed above the P-side electrode,
wherein each of both ends of the pad electrode in the resonance direction is located between a corresponding one of the two end faces and the ridge portion.

13. The semiconductor laser element according to claim 1,
wherein the semiconductor laser element is of a gain-guiding type.

14. The semiconductor laser element according to claim 3,
wherein the semiconductor stack includes two wing portions each of which includes a portion of the P-type contact layer and extends in the resonance direction,
at least a portion of the ridge portion is disposed between the two wing portions in the top view of the semiconductor stack,
each of the two wing portions is adjacent to the ridge portion with the bottom portion being interposed therebetween,
the two wing portions protrude upward from the bottom portion, and
a height of the two wing portions from the bottom portion is equal to a height of the ridge portion from the bottom portion.

15. The semiconductor laser element according to claim 14,
wherein each of the two wing portions extends to the two end faces.

16. The semiconductor laser element according to claim 3,
wherein the semiconductor stack includes a window region adjacent to a front end face through which the laser light is emitted, the front end face being one of the two end faces, and
bandgap energy of the active layer in the window region is greater than bandgap energy of the active layer in a region other than the window region.

17. The semiconductor laser element according to claim 16,
wherein the window region is in contact with the front end face, and
a length of the window region in the resonance direction is less than a length of the bottom portion in the resonance direction, the bottom portion being located between the front end face and the ridge portion.

18. The semiconductor laser element according to claim 3, further comprising:
an insulating film disposed above the semiconductor stack,
wherein the insulating film includes an opening portion in a region corresponding to the current injection window.

19. The semiconductor laser element according to claim 3,
wherein an oxygen concentration in the bottom portion is higher than an oxygen concentration inside the semiconductor stack.

20. The semiconductor laser element according to claim 3, further comprising:
a P-side electrode in contact with the P-type contact layer, and a pad electrode disposed above the P-side electrode,
wherein each of both ends of the pad electrode in the resonance direction is located between a corresponding one of the two end faces and the ridge portion.

21. The semiconductor laser element according to claim 4,
wherein the semiconductor stack includes two wing portions that include a portion of the P-type contact layer and extend in the resonance direction,
at least a portion of the ridge portion is disposed between the two wing portions in the top view of the semiconductor stack,
each of the two wing portions is adjacent to the ridge portion with the bottom portion being interposed therebetween,
the two wing portions protrude upward from the bottom portion, and
a height of the two wing portions from the bottom portion is equal to a height of the ridge portion from the bottom portion.
